(19) United States
(12) Patent Application Publication
(10) Pub. No.: US 2019/0044091 A1
(43) Pub. Date: Feb. 7, 2019

(54) ORGANIC ELECTROLUMINESCENCE PANEL AND METHOD FOR MANUFACTURING THE SAME

(71) Applicant: KONICA MINOLTA, INC., Tokyo (JP)

(72) Inventors: Kazuyoshi OMATA, Koufu-shi (JP); Tsukasa YAGI, Kobe-shi (JP)

(73) Assignee: Konica Minolta, Inc., Tokyo (JP)

(21) Appl. No.: 15/759,689

(22) PCT Filed: Aug. 1, 2016
(86) PCT No.: PCT/JP2016/072556

§ 371 Date: Mar. 13, 2018

(30) Foreign Application Priority Data
Sep. 29, 2015 (JP) 2015-190717

(51) Int. Cl. H01L 51/52; H01L 51/00; H01L 27/32; H01L 51/56

(52) U.S. Cl. CPC H01L 51/5234; H01L 51/5206; H01L 51/0097; H01L 51/5253; H01L 27/3204; H01L 2251/558; H01L 51/0018; H01L 2251/5338; H01L 2251/301; H01L 2251/5323; H01L 51/56

(57) ABSTRACT

An object of the present invention is to provide an organic EL panel including a light-transmissive organic EL element, having a wide light-emitting area constituted by a plurality of divided light-emitting areas, and having improved luminance uniformity and stability, and a method for manufacturing the organic EL panel.

An organic EL panel of the present invention includes an organic EL element having a light transmittance of 50% or more at a wavelength of 550 nm during non-emission of light, and is characterized in that, in the organic EL element, a light-emitting area constituted by at least a positive electrode, an organic functional layer unit, and a negative electrode is divided into a plurality of parts on a substrate, both the positive electrode and the negative electrode constituting the light-emitting area are constituted by light-transmissive electrodes, the negative electrode is separated by a separator disposed on the positive electrode, and a positive electrode constituting one of the divided light-emitting areas is electrically connected in series to a negative electrode constituting another adjacent light-emitting area.

### TECHNICAL FIELD

The present invention relates to a light-transmissive organic electroluminescence panel applied to various display apparatuses (hereinafter, also referred to as “displays”), lighting apparatuses, and the like, and a method for manufacturing the organic electroluminescence panel, and more specifically relates to an organic electroluminescence panel in which a plurality of light-emitting areas constituted by light-transmissive organic electroluminescence elements is disposed and which has improved luminance uniformity and stability on a wide light-emitting area, and a method for manufacturing the organic electroluminescence panel.

### BACKGROUND ART

An organic electroluminescence L element (hereinafter, abbreviated as an “organic EL element”) utilizing electroluminescence (hereinafter, abbreviated as “EL”) of an organic material is a thin film type complete solid-state element capable of emitting light at a low voltage of about several V to several tens of V, and has many excellent characteristics such as high luminance, high luminous efficiency, thin type, and light weight. For this reason, the organic EL element has attracted attention in recent years as a surface light emitter of a back light for various displays, a smart device, an illumination light source, or the like.

Such an organic EL element has a configuration in which a light-emitting layer formed of an organic material is sandwiched between two opposing electrodes, and light emitted from the light-emitting layer passes through the electrodes and is extracted to an outside. Therefore, at least one of the two electrodes is constituted as a light-transmissive electrode (hereinafter, also referred to as a transparent electrode).

As a light-transmissive electrode, an oxide semiconductor-based material such as indium tin oxide (SnO₂—In₂O₃, hereinafter, abbreviated as “ITO”) is generally used.

For example, JP 2008-524819 A, JP 2013-004245 A, JP 2013-242998 A, and the like disclose studies on a dual emission type light-transmissive organic electroluminescence element from a viewpoint of expanding a field of application of a display using an organic electroluminescence element.

In such a dual emission type organic electroluminescence element, both a positive electrode and a negative electrode are constituted by a pair of light-transmissive transparent electrodes with a light-emitting layer interposed therebetween. As such a light-transmissive electrode, ITO has been generally used as described above. However, ITO has a large work function, and therefore ITO has excellent performance as a positive electrode, but tends to have poor performance as a negative electrode. For this reason, a light-transmissive display having a light-emitting portion and a see-through portion (light-transmitting portion) is disclosed in which, as electrodes for a light-transmissive display using light-transmissive electrodes on both sides, in order to obtain high performance with the present technology, electrodes of ITO-ITO for both a positive electrode and a negative electrode are not used but electrodes such as positive electrode ITO-negative electrode aluminum are used to make the area of the negative electrode as small as possible (for example, refer to Patent Literature 1). Furthermore, a light-transmissive electrode constituted using silver having a high electric conductivity or an alloy of silver and aluminum as a negative electrode is known. However, in a light-transmissive organic electroluminescence element, many of thin film metal layers and oxide semiconductors used for a positive electrode and a negative electrode have high resistance values and large voltage drops. Particularly, in a case where a light-transmissive electrode is thinned or a light-emitting area of an element is increased in order to improve luminous efficiency, a sheet resistance value is increased and luminance uniformity is largely deteriorated disadvantageously. This is a large obstacle to development of an organic electroluminescence element aiming at a large area and high luminance in the future.

An increase in size of an organic electroluminescence element makes it difficult to obtain a uniform current density in a plane direction at each position of a light-emitting layer. As a result, the following phenomenon is presumed as a cause of occurrence of luminance unevenness, a difference in element lifetime, or chromaticity unevenness.

A cause of occurrence of luminance unevenness due to an increase in the area is as follows. That is, there are a portion where a large amount of current flows and a portion where only a small amount of current flows in a light-emitting screen due to an increase in size of the screen, and therefore luminance unevenness occurs as an entire organic EL element. The luminance of an organic EL element is higher as the amount of a flowing current is larger. Therefore, if there are a portion where a large amount of current flows and a portion where only a small amount of current flows, a difference in luminance occurs between the portions, and causes luminance unevenness.

Furthermore, with an increase in size, a difference in lifetime occurs in each light-emitting region in an organic EL element. This is because the lifetime of the organic EL element is different between a portion where a large amount of current flows and a portion where only a small amount of current flows. Generally, the lifetime of a portion where a large amount of current flows is short. Therefore, as compared with an element in which a current flows uniformly, there is a portion having a short lifetime, and the lifetime as the organic EL element is short.

In order to solve such a problem, various techniques have been proposed hitherto.

For example, JP 5-315073 A discloses a technique for disposing many extraction portions (the above terminal portions) for voltage application. However, the size of an apparatus such as a portable terminal in which an organic EL element is incorporated is limited, and therefore the size of the organic EL element is also limited. That is, in order to increase the light-emitting area of the organic EL element, the total area of the terminal portions needs to be reduced. In addition, a ratio of a region occupied by wiring connecting the terminal portions to an external driving circuit needs to be taken into consideration. Therefore, as in this related art, it is effective to dispose many extraction portions for solving the above problem, but it is extremely difficult to adopt this configuration for practical use.

Meanwhile, a technique relating to a line arrangement type light source in which a light-emitting region is divided into a plurality of parts and the divided light-emitting regions are connected to one another in series, has also been proposed (for example, refer to Patent Literature 2). More specifically, this is a technique in which, by connecting a plurality of thin type light-emitting elements (light-emitting regions) to one another in series and further making the areas of the thin type light-emitting elements equal to one another, current densities in the light-emitting elements are made to be equal to one another, and luminances of the thin type light-emitting elements are thereby made to be equal to one another. In addition, an organic EL element in which a plurality of light-emitting regions is disposed, an insulating portion is disposed between light-transmissive electrodes in physically adjacent light-emitting regions, and the plurality of light-emitting regions is electrically connected to one another in series, is disclosed (for example, refer to Patent Literature 3).

However, even if an organic EL element is manufactured based on Examples and the like disclosed in the above Patent Literatures 2 and 3, a failure may be easily generated disadvantageously, for example, a positive electrode and a negative electrode in each light-emitting region may be short-circuited or a light-emitting region where no light is emitted may be generated.

Meanwhile, a transparent organic EL element including a first transparent electrode, an insulating partition wall, an organic EL layer, and a second transparent electrode separated by the partition wall on a transparent substrate, is disclosed (for example, refer to Patent Reference 4).

According to Patent Literature 4, resistance of the second transparent electrode layer can be reduced without causing a short circuit even if alignment deviates. However, as a result of studies on the specific configuration disclosed in Patent Literature 4, the following fact has been revealed. That is, the first transparent electrode and the second transparent electrode constituting each divided light-emitting area are not directly connected to each other, and therefore a current value in each organic EL element is high, nonuniformity of light emission occurs, and cutting of wiring connecting the electrodes or a short circuit between the electrodes easily occurs in a case of use under severe conditions.

### CITATION LIST

### Patent Literature

Patent Literature 1: JP 2012-014859 A

Patent Literature 2: JP 2000-173771 A

Patent Literature 3: JP 2005-116193 A

Patent Literature 4: JP 2011-216317 A

### SUMMARY OF INVENTION

### Technical Problem

The present invention has been achieved in view of the above problems, and a problem to be solved is to provide an organic electroluminescence panel including a light-transmissive organic electroluminescence element, having a wide light-emitting area constituted by a plurality of divided light-emitting areas, and having improved luminance uniformity and stability, and a method for manufacturing the organic electroluminescence panel.

### Solution to Problem

As a result of intensive studies in view of the above problems, the present inventors have found that an organic electroluminescence panel capable of increasing a light-emitting area and reducing a current value required for light emission in each organic EL element, and having improved luminance uniformity and stability can be realized due to an organic electroluminescence panel characterized in that the organic electroluminescence panel includes a dual emission type light-transmissive organic electroluminescence element, the organic electroluminescence element has a configuration in which a light-emitting area constituted by at least a light-transmissive positive electrode, an organic functional layer unit, and a light-transmissive negative electrode is divided into a plurality of parts on a substrate, the negative electrode is separated by a separator disposed on the positive electrode, and the positive electrode constituting one of the divided light-emitting areas is electrically connected in series to the negative electrode constituting another light-emitting area. The present inventors have thereby completed the present invention.

That is, the above problems of the present invention are solved by the following means.

1. An organic electroluminescence panel including an organic electroluminescence element having a light transmittance of 50% or more at a wavelength of 550 nm during non-emission of light, characterized in that

in the organic electroluminescence element, a light-emitting area constituted by at least a positive electrode, an organic functional layer unit, and a negative electrode is divided into a plurality of parts on a substrate,

both the positive electrode and the negative electrode constituting the light-emitting area are constituted by light-transmissive electrodes,

the negative electrode is separated by a separator disposed on the positive electrode, and

a positive electrode constituting one of the divided light-emitting areas is electrically connected in series to a negative electrode constituting another adjacent light-emitting area.

2. The organic electroluminescence panel according to the first item, characterized in that an insulating layer is disposed between the positive electrode and the separator.

3. The organic electroluminescence panel according to the first or second item, characterized in that the substrate is a light-transmissive glass substrate or flexible resin substrate.

4. The organic electroluminescence panel according to the third item, characterized in that the flexible resin substrate has a gas barrier layer.

5. The organic electroluminescence panel according to any one of the first to fourth items, characterized in that the light-transmissive positive electrode is formed of an oxide semiconductor or a thin film metal or alloy.

6. The organic electroluminescence panel according to any one of the first to fifth items, characterized in that the light-transmissive negative electrode is formed of at least a thin film metal or alloy.

7. The organic electroluminescence panel according to any one of the first to sixth items, characterized in that the light-transmissive negative electrode includes a base layer formed using a nitrogen-containing compound and an electrode layer formed of silver or an alloy containing silver as a main component on the base layer.

8. The organic electroluminescence panel according to any one of the first to seventh items, characterized in that a connecting portion between the organic electroluminescence panel and an external electrode is electrically connected by a conductive adhesive.

9. The organic electroluminescence panel according to any one of the first to eighth items, characterized in that the plurality of organic electroluminescence elements is sealed with a flexible resin member having a gas barrier layer.

10. The organic electroluminescence panel according to any one of the first to ninth items, characterized in that the plurality of light-emitting areas is separated from one another by the separators and is arranged in parallel in stripes.

11. The organic electroluminescence panel according to any one of the eighth to tenth items, characterized in that the external electrode is formed of a light-transmissive flexible printed circuit.

12. A method for manufacturing an organic electroluminescence panel for manufacturing the organic electroluminescence panel according to any one of the first to eleventh items, characterized in that

the organic electroluminescence panel includes an organic electroluminescence element having a light transmittance of 50% or more at a wavelength of 550 nm during non-emission of light,

in the organic electroluminescence element, a light-emitting area constituted by at least a positive electrode, an organic functional layer unit, and a negative electrode is formed on a substrate while being divided into a plurality of parts,

a pattern in which the negative electrode is separated by a separator disposed on the positive electrode is formed,

a positive electrode constituting one of the divided light-emitting areas is electrically connected in series to a negative electrode constituting another adjacent light-emitting area, and

the positive electrode, the negative electrode, and the separator are formed by a photolithography method.

13. The method for manufacturing an organic electroluminescence panel according to the twelfth item, characterized in that an insulating layer is formed between the positive electrode and the separator using a photolithography method.

### Advantageous Effects of Invention

The present invention can provide an organic electroluminescence panel having a wide light-emitting area constituted by a plurality of divided light-emitting areas and having improved luminance uniformity and stability, and a method for manufacturing the organic electroluminescence panel.

Technical characteristics of the organic electroluminescence panel having the configuration defined in the present invention and a mechanism of developing an effect thereof are presumed as follows.

Usually, in a case where the area of a light-transmissive organic electroluminescence element is increased, the amount of a current supplied is large. Therefore, an influence of voltage drop of a positive electrode or a negative electrode from a power supply end to a central part of a panel is large, and luminance unevenness occurs disadvantageously.

In the organic electroluminescence panel of the present invention, the light-emitting area is divided into a plurality of parts (the number of division is represented by N), a positive electrode constituting one of the light-emitting areas is electrically connected in series to a negative electrode constituting another light-emitting area, and the required amount of a current is thereby reduced to I/N. As a result, voltage drop of the positive electrode or the negative electrode from a power supply end to a central part of the panel is also reduced to I/N. As a result, it has become possible to realize a large area organic electroluminescence panel having excellent light emission uniformity.

### BRIEF DESCRIPTION OF DRAWINGS

FIG. 1 is a schematic cross-sectional view exemplifying a configuration of an organic EL element applicable to the present invention.

FIG. 2 is a schematic cross-sectional view exemplifying a configuration of an organic EL panel of the present invention (first embodiment).

FIG. 3 is a schematic cross-sectional view exemplifying the configuration of the organic EL panel of the present invention, having an insulating layer (second embodiment).

FIG. 4 is a schematic cross-sectional view exemplifying the configuration of the organic EL panel of the present invention, having a gas barrier layer (third embodiment).

FIG. 5 illustrates a top view and a schematic cross-sectional view of an organic EL panel having a plurality of light-emitting areas arranged in stripes (fourth embodiment).

FIG. 6A is a schematic circuit diagram exemplifying a circuit configuration of an organic EL panel in Comparative Example.

FIG. 6B is a schematic circuit diagram exemplifying a circuit configuration of the organic EL panel of the present invention.

FIG. 7 is a schematic cross-sectional view exemplifying the configuration of the organic EL panel of the present invention, including a sealing member (fifth embodiment).

FIG. 8 is a process flow diagram exemplifying procedures for manufacturing the organic EL panel of the fifth embodiment illustrated in FIG. 7 (sixth embodiment).

FIG. 9 is a schematic sectional view illustrating another example of the configuration of the organic EL element applicable to the present invention (seventh embodiment).

FIG. 10 is a schematic cross-sectional view illustrating another example of the configuration of the organic EL element applicable to the present invention (eighth embodiment).

FIG. 11 is a schematic view exemplifying an electrical connection method between an organic EL panel applicable to the present invention and an external electrode (ninth embodiment).

### DESCRIPTION OF EMBODIMENTS

An organic electroluminescence panel of the present invention includes an organic electroluminescence element having a light transmittance of 50% or more at a wavelength of 550 nm during non-emission of light, and is characterized in that, in the organic electroluminescence element, a light-emitting area constituted by at least a positive electrode, an organic functional layer unit, and a negative electrode is divided into a plurality of parts on a substrate, both the positive electrode and the negative electrode constituting the light-emitting area are constituted by light-transmissive electrodes, the negative electrode is separated by a separator disposed on the positive electrode, and a positive electrode constituting one of the divided light-emitting areas is electrically connected in series to a negative electrode constituting another adjacent light-emitting area. This characteristic is a technical characteristic common or corresponding to the invention according to claims.

As an embodiment of the present invention, from a viewpoint of being able to further exhibit an intended effect of the present invention, an insulating layer is preferably further disposed between the positive electrode and the separator from a viewpoint of being able to further enhance a better insulating property between the electrodes in the same light-emitting area and to further improve stability.

A light-transmissive glass substrate or flexible resin substrate is preferably applied as the substrate from a viewpoint of being able to realize a higher light-transmissive property.

In a case where a flexible resin substrate is used as the substrate, a gas barrier layer is preferably formed between the flexible resin substrate and the organic EL constituting layer from a viewpoint of being able to eliminate an influence of moisture, oxygen, or the like on the organic EL constituting layer and being able to obtain high durability.

The light-transmissive positive electrode is preferably formed of an oxide semiconductor or a thin film metal or alloy from a viewpoint of being able to obtain an electrode having both a high light-transmissive property and excellent conductivity.

The light-transmissive negative electrode is preferably formed of at least a thin film metal or alloy from a viewpoint of being able to obtain an electrode having both a high light-transmissive property and excellent conductivity.

In a case where an electrode layer formed of silver or an alloy containing silver as a main component is applied as the light-transmissive negative electrode, preferably, a base layer formed using a nitrogen-containing compound is disposed and the electrode layer is formed on the base layer from a viewpoint of being able to make silver atoms exist without causing aggregation or the like and to form a uniform thin silver film.

A connecting portion between the organic electroluminescence panel and an external electrode is preferably electrically connected by a conductive adhesive.

The plurality of organic electroluminescence elements is preferably sealed with a flexible resin substrate having a gas barrier layer from a viewpoint of being able to eliminate an influence of moisture, oxygen, or the like on the organic EL constituting layers and to obtain high durability.

The plurality of light-emitting areas is preferably arranged in parallel in stripes from a viewpoint of being able to obtain a stable light-emitting characteristic by efficiently dividing a wide area.

The external electrode is preferably formed of a light-transmissive flexible printed circuit from a viewpoint of being able to design a highly light-transmissive circuit with a thin film.

A preferable method for manufacturing the organic electroluminescence panel of the present invention is a method for manufacturing an organic electroluminescence panel, characterized in that the organic electroluminescence panel includes an organic electroluminescence element having a light transmittance of 50% or more at a wavelength of 550 nm during non-emission of light, in the organic electroluminescence element, a light-emitting area constituted by at least a positive electrode, an organic functional layer unit, and a negative electrode is formed on a substrate while being divided into a plurality of parts, a pattern in which the negative electrode is separated by a separator disposed on the positive electrode is formed, a positive electrode constituting one of the divided light-emitting areas is electrically connected in series to a negative electrode constituting another adjacent light-emitting area, and the positive electrode, the negative electrode, and the separator are formed by a photolithography method, from a viewpoint of being able to manufacture an organic electroluminescence panel capable of forming a high definition constituent pattern and forming a narrow non-light-emitting area.

An insulating layer is preferably formed between the positive electrode and the separator using a photolithography method from a viewpoint of being able to obtain a high insulating property and to form a high definition insulating layer.

The “organic EL panel” referred to in the present invention means a panel in which a plurality of organic EL elements constituting light-emitting areas divided into a plurality of parts is arranged on the same plane, and a positive electrode in one of the organic EL elements is electrically in contact with another adjacent negative electrode to constitute a large area light emitter.

The “organic EL element” referred to in the present invention is an element constituting a divided light-emitting area, and includes a pair of opposing light-transmissive electrodes (positive electrode and negative electrode) on a substrate and an organic functional layer unit mainly including a carrier transport functional layer for controlling transport of electrons or holes and a light-emitting layer between the light-transmissive electrodes, and further includes a sealing member on the organic functional layer unit. However, description or explanation of the sealing member may be omitted for the sake of explanation. In the present invention, description of a control circuit for controlling light emission of the organic EL element and wiring is omitted.

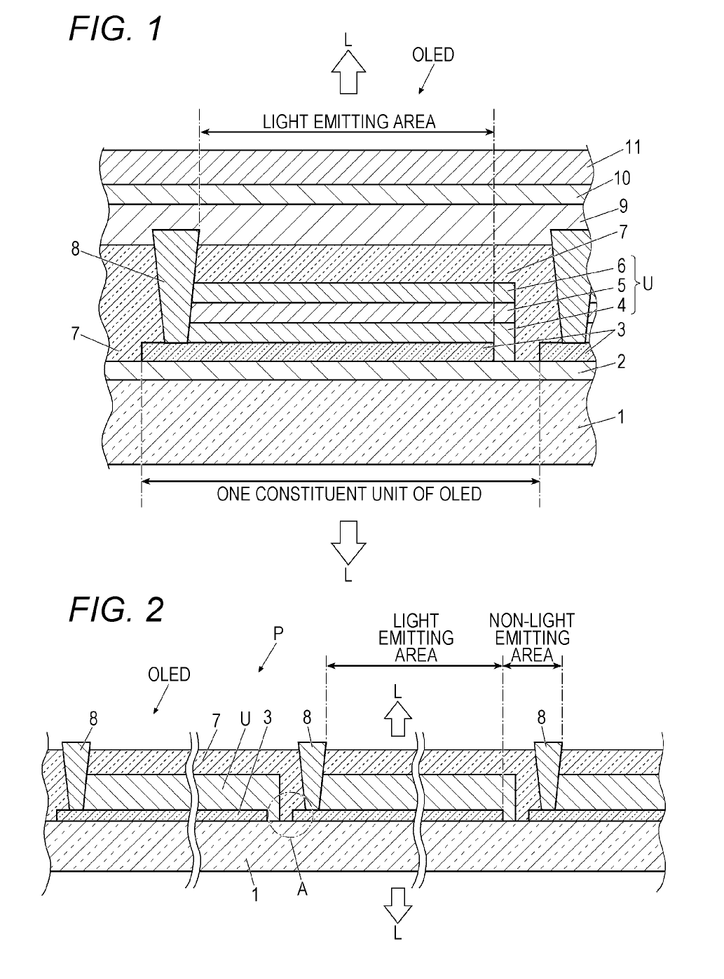

The “organic functional layer unit” referred to in the present invention will be described below with reference to FIG. 1. However, as an example, the organic functional layer unit has a configuration in which a first carrier transport functional layer group 1 (for example, a hole injection layer or a hole transport layer), a light-emitting layer containing a phosphorescent compound or the like, and a second carrier transport functional layer group 2 (for example, a hole blocking layer, an electron transport layer, or an electron injection layer) are laminated on a substrate.

The “light-emitting area” referred to in the present invention means a region in which all the constituent elements of the positive electrode, the organic functional layer unit, and the negative electrode exist in a layer thickness direction.

The “positive electrode” referred to in the present invention is an electrode to which (+) is applied as a voltage, and may be referred to as an “anode” or a “first electrode”. The “negative electrode” is an electrode to which (−) is applied as a voltage, and may be referred to as a “cathode” or a “second electrode”.

The term “light-transmissive” referred to in the present invention means that the light transmittance at a wavelength of 550 nm is 50% or more, preferably 60% or more, and more preferably 70% or more.

Hereinafter, the constituent elements of the present invention and embodiments for performing the present invention will be described in detail with reference to the drawings. In the present application, “to” representing a numerical range means inclusion of numerical values described before and after “to” as a lower limit value and an upper limit value. In description of the figures, the number described in parentheses at an end of a constituent element represents a reference sign in the figures.

<<Basic Configuration of Organic EL Element>>

First, a basic configuration of the organic EL element will be described with reference to the drawings.

The organic EL panel of the present invention is characterized in that an organic EL element to be applied is a dual emission type organic EL element having a light transmittance of 50% or more at a wavelength of 550 nm during non-emission of light.

FIG. 1 is a schematic cross-sectional view illustrating a basic configuration including an organic functional layer unit of an organic EL element applicable to the present invention.

The organic EL element (OLED) according to the present invention illustrated in FIG. 1 has a configuration in which a positive electrode (3), an organic functional layer unit (U) including a light-emitting layer and a carrier transport functional layer, a negative electrode (7), and the like are laminated on a light-transmissive substrate (1), for example, a glass substrate or a flexible resin substrate.

The organic EL element (OLED) illustrated in FIG. 1 illustrates an example in which a gas barrier layer (2) is formed on the light-transmissive substrate (1). In a light-emitting area formed while being divided on the gas barrier layer (2), the positive electrode (3) is formed as a first electrode and a separator (8) is disposed on one end portion (the left side in FIG. 1) of the positive electrode (3). The shape of the separator (8) is not particularly limited, and examples of the shape include a rectangular shape, a trapezoidal shape, and an inverted tapered shape. However, the shape of the separator (8) preferably has an inverted tapered overhang structure as illustrated in FIG. 1. This separator (8) may be referred to as a partition wall or a cathode separator.

Meanwhile, on a region other than the region of the positive electrode (3) where the separator (8) is formed, the first carrier transport functional layer group 1 (4) including, for example, a hole injection layer and a hole transport layer, a light-emitting layer (5), and the second carrier transport functional layer group 2 (6) including, for example, an electron transport layer and an electron injection layer are laminated to constitute the organic functional layer unit (U).

The negative electrode (7) is further disposed as a second electrode in an independent pattern between the separators (8) in one organic EL element (OLED) and another adjacent organic EL element. A sealing substrate (11) having a sealing adhesive layer (9) and a gas barrier layer (10) is disposed so as to cover the entire laminated body having the above configuration to constitute an organic EL element (OLED). At this time, a positive electrode (3) constituting one of the divided light-emitting areas is electrically connected in series to a negative electrode (3) constituting another adjacent light-emitting area.

The present invention is characterized in that, in the configuration illustrated in FIG. 1, each of the positive electrode (3) as a first electrode and the negative electrode (7) as a second electrode is an electrode having a light transmittance of 50% or more at a wavelength of 550 nm.

By constituting each of the positive electrode and the negative electrode by a light-transmissive electrode in this way, it is possible to extract emitted light (L) emitted from a light-emitting layer of the organic functional layer unit or an interface thereof to an outside from a light-emitting area on the substrate (1) surface on a side of the light-transmissive first electrode (3) and a light-emitting area on the sealing member (11) surface side on a side of the light-transmissive second electrode (7).

As illustrated in FIG. 1, the light-emitting area means a region in which all the constituent elements of the positive electrode (3), the organic functional layer unit (U), particularly the light-emitting layer (5), and the negative electrode (7) exist on the same plane.

The organic EL panel of the present invention is characterized in that a light-emitting area including at least the positive electrode (8), the organic functional layer unit (U), and the negative electrode (7) is disposed on a substrate while being divided into a plurality of parts via the separators (8), and a positive electrode constituting one of the divided light-emitting areas is electrically connected in series to a negative electrode constituting another adjacent light-emitting area. Specifically, as illustrated in FIG. 1, the organic EL panel of the present invention is characterized in that the positive electrode (3) constituting an organic EL element (OLED) illustrated as “one constituent unit of OLED” is electrically connected to the negative electrode (7) disposed on the left side (not described specifically), the negative electrode (7) of an organic EL element (OLED) illustrated as “one constituent unit of OLED” is electrically connected to the positive electrode (3) disposed on the right side (not described specifically), and the plurality of light-emitting areas (organic EL elements) is connected to one another in series.

Furthermore, in the organic EL element according to the present invention, a tandem type configuration in which two or more organic functional layer units are laminated may be used.

In this way, in the organic EL panel of the present invention, it has been able to reduce a current value required for light emission and to realize a large area organic EL panel having excellent luminance uniformity by dividing a light-emitting area into a plurality of parts via the separators (8), and electrically connecting a positive electrode constituting one of the divided light-emitting areas in series to a negative electrode constituting another adjacent light-emitting area.

[Constituent Element of Organic EL Element]

First, a main constituent element of the organic EL element constituting the organic EL panel of the present invention will be described in detail.

In the light-transmissive organic EL element (OLED) according to the present invention, a light-transmissive positive electrode (3) as a first electrode is formed on a substrate (1) having a gas barrier layer (2) in a divided region on the gas barrier layer (2), and an inverted trapezoidal separator (8) is disposed on one end portion (the left side in FIG. 1) of the positive electrode (3), although the above description in FIG. 1 is repeated.

Subsequently, on a region other than the region of the positive electrode (3) where the separator (8) is formed, a carrier transport functional layer group 1 (4) including, for example, a hole injection layer and a hole transport layer, a light-emitting layer (5), and a carrier transport functional layer group 2 (6) including, for example, an electron transport layer and an electron injection layer are laminated to constitute a light-emitting region. Furthermore, in an upper region separated by a pair of separators (8), a light-transmissive negative electrode (7) as a second electrode is formed, and a sealing substrate (11) having a sealing adhesive layer (9) and a gas barrier layer (10) is disposed on the negative electrode (7).

Typical examples of the configuration of the organic EL element are illustrated below.

(i) light-transmissive positive electrode (3)/separator (8)/organic functional layer unit (U) [carrier transport functional layer group 1 (4: hole injection transport layer)/light-emitting layer (5)/carrier transport functional layer group 2 (6: electron injection transport layer)]/light-transmissive negative electrode (7)

(ii) light-transmissive positive electrode (3)/separator (8)/organic functional layer unit (U) [carrier transport functional layer group 1 (4: hole injection transport layer)/light-emitting layer (5)/carrier transport functional layer group 2 (6: hole blocking layer/electron injection transport layer)]/light-transmissive negative electrode (7)

(iii) light-transmissive positive electrode (3)/separator (8)/organic functional layer unit (U) [carrier transport functional layer group 1 (4: hole injection transport layer/electron blocking layer)/light-emitting layer (5)/carrier transport functional layer group 2 (6: hole blocking layer/electron injection transport layer)]/light-transmissive negative electrode (7)

(iv) light-transmissive positive electrode (3)/separator (8)/organic functional layer unit (U) [carrier transport functional layer group 1 (4: hole injection layer/hole transport layer)/light-emitting layer (5)/carrier transport functional layer group 2 (6: electron transport layer/electron injection layer)]/light-transmissive negative electrode (7)

(v) light-transmissive positive electrode (3)/separator (8)/organic functional layer unit (U) [carrier transport functional layer group 1 (4: hole injection layer/hole transport layer)/light-emitting layer (5)/carrier transport functional layer group 2 (6: hole blocking layer/electron transport layer/electron injection layer)]/light-transmissive negative electrode (7)

(vi) light-transmissive positive electrode (3)/separator (8)/organic functional layer unit (U) [carrier transport functional layer group 1 (4: hole injection layer/hole transport layer/electron blocking layer)/light-emitting layer (5)/carrier transport functional layer group 2 (6: hole blocking layer/electron transport layer/electron injection layer)]/light-transmissive negative electrode (7)

Furthermore, in addition to the above configurations, a configuration in which an insulating layer (12) described below is disposed between the positive electrode (3) and the separator (8) is also preferable.

An outline of an organic EL element applicable to the present invention is described, for example, in JP 2013-157634 A, JP 2013-168552 A, JP 2013-177361 A, JP 2013-187211 A, JP 2013-191644 A, JP 2013-191804 A, JP 2013-225678 A, JP 2013-235994 A, JP 2013-243234 A, JP 2013-243236 A, JP 2013-242366 A, JP 2013-243371 A, JP 2013-245179 A, JP 2014-003249 A, JP 2014-003299 A, JP 2014-013910 A, JP 2014-017493 A, JP 2014-017494 A, and the like.

Furthermore, a tandem type organic EL element can be used. Specific examples of the tandem type include element configurations and constituent materials described in U.S. Pat. No. 6,337,492, U.S. Pat. No. 7,420,203, U.S. Pat. No. 7,473,923, U.S. Pat. No. 6,872,472, U.S. Pat. No. 6,107,734, U.S. Pat. No. 6,337,492, WO 2005/009087 A, JP 2006-228712 A, JP 2006-24791 A, JP 2006-49393 A, JP 2006-49394 A, JP 2006-49396 A, JP 2011-96679 A, JP 2005-340187 A, JP 4711424 B2, JP 3496681 B2, JP 3884564 B2, JP 4213169 B2, JP 2010-192719 A, JP 2009-076929 A, JP 2008-078414 A, JP 2007-059848 A, JP 2003-272860 A, JP 2003-045676 A, and WO 2005/094130 A. However, the present invention is not limited thereto.

Furthermore, each constituent element of the organic EL element will be described in detail.

[Substrate]

The substrate (1) applicable to the organic EL element (OLED) is not particularly limited as long as being a light-transmissive substrate, and examples of the substrate (1) include glass and a resin substrate.

Examples of the light-transmissive substrate (1) applicable to the present invention include glass, quartz, and a resin substrate. However, a flexible resin substrate is more preferable from a viewpoint of being able to impart flexibility to the organic EL element.

Examples of a resin material constituting a resin substrate applicable to the present invention include a polyester such as polyethylene terephthalate (abbreviation: PET) or polyethylene naphthalate (abbreviation: PEN), polyethylene, polypropylene, a cellulose ester and a derivative thereof such as cellophane, cellulose diacetate, cellulose triacetate (abbreviation: TAC), cellulose acetate butyrate, cellulose acetate propionate (abbreviation: CAP), cellulose acetate phthalate, or cellulose nitrate, polyvinylidene chloride, polyvinyl alcohol, polyethylene vinyl alcohol, syndiotactic polystyrene, polycarbonate (abbreviation: PC), a norbornene resin, polymethylpentene, polyetherketone, polyimide, polyethersulfone (abbreviation: PES), polyphenylene sulfide, a polysulfone, polyether imide, polyether ketone imide, polyamide, fluororesin, nylon, polymethyl methacrylate, an acrylate, a polyarylate, and a cycloolefin-based resin such as Arton (trade name, manufactured by JSR Corporation) or Apel (trade name, manufactured by Mitsui Chemicals, Inc.).

Among these resin substrates, a flexible resin substrate such as polyethylene terephthalate (abbreviation: PET), polybutylene terephthalate, polyethylene naphthalate (abbreviation: PEN), or polycarbonate (abbreviation: PC) can be preferably used from a viewpoint of cost and easy availability.

The above resin substrate may be an unstretched film or a stretched film.

The resin substrate applicable to the present invention can be manufactured by a conventionally known film forming method. For example, an unstretched resin substrate which is substantially amorphous and unoriented can be manufactured by melting a resin as a material with an extruder, extruding the resin with a circular die or a T die, and rapidly cooling the resin. In addition, a resin substrate manufactured by a solution casting method in which a resin component is dissolved in a solvent to prepare a dope, the dope is cast on a metal support, and the dope is dried to form a film can also be applied. Furthermore, a stretched resin substrate can be manufactured by stretching an unstretched resin substrate in a conveyance direction of the resin substrate (longitudinal axis direction, MD direction) or a direction perpendicular to the conveyance direction of the resin substrate (transverse axis direction, TD direction) by a known method such as uniaxial stretching, tenter type sequential biaxial stretching, tenter type simultaneous biaxial stretching, or tubular type simultaneous biaxial stretching. In this case, a stretching magnification can be appropriately selected according to a resin as a raw material of the resin substrate, but is preferably within a range of 1.01 to 10 times in each of the longitudinal axis direction and the transverse axis direction.

The resin substrate is preferably a thin film resin substrate having a thickness within a range of 3 to 200 μm, more preferably in a range of 10 to 150 μm, particularly preferably in a range of 20 to 120 μm.

Examples of a glass substrate applicable as the light-transmissive substrate according to the present invention include soda-lime glass, barium/strontium-containing glass, lead glass, aluminosilicate glass, borosilicate glass, barium borosilicate glass, and quartz.

[First Electrode: Light-Transmissive Positive Electrode]

The light-transmissive positive electrode constituting the organic EL element is preferably formed of an oxide semiconductor or a thin film metal or alloy. Examples thereof include a metal such as Ag or Au, an alloy containing the metal as a main component, CuI, and an oxide semiconductor such as indium.tin composite oxide (ITO), SnO₂, or ZnO.

In a case where the light-transmissive positive electrode contains silver as a main component, the purity of silver is preferably 99% or more. Palladium (Pd), copper (Cu), gold (Au), or the like may also be added in order to ensure stability of silver.

The light-transmissive positive electrode can be formed into a layer containing silver as a main component. Specifically, the light-transmissive positive electrode may be formed of silver alone or an alloy containing silver (Ag). Examples of such an alloy include silver.magnesium (Ag.Mg), silver.copper (Ag.Cu), silver.palladium (Ag.Pd), silver.palladium.copper (Ag.Pd.Cu), and silver.indium (Ag.In).

Among the constituent materials constituting the positive electrode, the positive electrode constituting the organic EL element according to the present invention is preferably a light-transmissive positive electrode containing silver as a main component and having a thickness within a range of 2 to 20 nm. The thickness is more preferably within a range of 4 to 12 nm. The thickness of 20 nm or less is preferable because an absorption component and a reflection component of the light-transmissive positive electrode can be kept low and a high light transmittance can be maintained.

The “layer containing silver as a main component” referred to in the present invention means that the content of silver in the light-transmissive positive electrode is 60% by mass or more, preferably 80% by mass or more, more preferably 90% by mass or more, and particularly preferably 98% by mass or more. In addition, the term “light-transmissive” referred to in the light-transmissive positive electrode according to the present invention means that the light transmittance at a wavelength of 550 nm is 50% or more.

In the light-transmissive positive electrode, the layer containing silver as a main component may by divided into a plurality of layers and laminated as necessary.

Furthermore, in the present invention, in a case where the positive electrode is a light-transmissive positive electrode containing silver as a main component, a base layer is preferably disposed under the positive electrode from a viewpoint of enhancing uniformity of a silver film of the light-transmissive positive electrode to be formed. The base layer is not particularly limited, but is preferably a layer containing an organic compound having a nitrogen atom or a sulfur atom. A method for forming a light-transmissive positive electrode containing silver as a main component on the base layer is preferable. Note that details of the base layer applicable to the present invention will be described below.

[Separator]

The present invention is characterized in that a separator is disposed between the organic EL elements, and the negative electrode is separated by two separators disposed on the positive electrode.

The separators according to the present invention are formed in stripes in a direction perpendicular to a longitudinal direction of the positive electrode. These separators have an insulating property and have a function of dividing the negative electrode into a plurality of areas.

In a case of a passive type light-transmissive organic EL element, positive electrodes are usually formed in stripes, and therefore separators are also formed in stripes so as to be perpendicular to a longitudinal direction of the stripe-shaped positive electrodes.

If a separator has a predetermined height, a negative electrode can be divided into a plurality of areas, and therefore a cross-sectional shape of the separator is not particularly limited. Examples of the shape include a rectangular shape, a trapezoidal shape (normal tapered shape), and an inverted tapered shape. An inverted tapered overhang structure as illustrated in FIG. 1 is preferable.

In a case where the separator has an inverted tapered shape, a taper angle θ with respect to a substrate or a surface of a positive electrode is only required to be 0°<θ<90°, but is preferably 20°<θ<80°, and more preferably 30°<θ<70°.

As the height of the separator, usually, the height from a surface of a positive electrode or an insulating layer as a base of the separator to a surface of the separator is set so as to be higher than the height from a surface of a substrate (1) to a surface of a negative electrode (7) at the center of a light-emitting region.

The width of the separator is not particularly limited, but is preferably 100 μm or less. A too wide width of the separator is not preferable because a light-emitting region is relatively narrow and the light-emitting area is reduced.

A pitch of the separator is not particularly limited, and is appropriately selected according to the size of a pixel of an intended organic EL element and the like.

Examples of a constituent material of the separator include a photocurable resin such as a photosensitive polyimide resin, an acrylic resin, a novolac-based resin, a styrene-based resin, a phenol-based resin, or a melamine-based resin, a thermosetting resin, and an inorganic material.

Examples of a method for forming the separator include a general method such as a photolithography method or a printing method. However, the method for manufacturing the organic electroluminescence panel of the present invention is characterized by forming the separator by a photolithography method. Details of the method for forming the separator by the photolithography method will be described below.

[Light-Emitting Layer]

In a light-emitting layer (5) constituting an organic EL element (OLED), a phosphorescence emission compound or a fluorescent compound can be used as a light-emitting material. However, in the present invention, a configuration containing a phosphorescence emission compound as a light-emitting material is particularly preferable.

This light-emitting layer is a layer that emits light by recombination of electrons injected from an electrode or an electron transport layer and holes injected from a hole transport layer. A light-emitting portion may be a region in the light-emitting layer or an interface region between the light-emitting layer and an adjacent layer.

The configuration of such a light-emitting layer is not particularly limited as long as a contained light-emitting material satisfies light emission requirements. Furthermore, there may be a plurality of layers having the same emission spectrum or emission maximum wavelength. In this case, a non-light-emitting intermediate layer is preferably disposed between the light-emitting layers.

The sum of the thicknesses of the light-emitting layers is preferably within a range of 1 to 100 nm, and more preferably within a range of 1 to 30 nm because a lower drive voltage can be obtained. Note that, in a case where a non-light-emitting intermediate layer is present between the light-emitting layers, the sum of the thicknesses of the light-emitting layers is the thickness including the intermediate layer.

The light-emitting layer as described above can be formed using a light-emitting material or a host compound described below by a known method such as a vacuum vapor deposition method, a spin coating method, a casting method, a Langmuir Blodgett method (LB method), or an inkjet method.

The light-emitting layer may be used by mixing a plurality of light-emitting materials, and may be used by mixing a phosphorescence emission material and a fluorescence emission material (also referred to as a fluorescent dopant or a fluorescent compound) in the same light-emitting layer. As a configuration of the light-emitting layer, the light-emitting layer preferably contains a host compound (also referred to as a light-emitting host or the like) and a light-emitting material (also referred to as a light-emitting dopant compound) to emit light from the light-emitting material.

<Host Compound>

As the host compound contained in the light-emitting layer, a compound having a phosphorescence quantum yield of less than 0.1 in phosphorescence emission at room temperature (25° C.) is preferable. Furthermore, the phosphorescence quantum yield is preferably less than 0.01. In addition, among the compounds contained in the light-emitting layer, a volume ratio of the host compound in the layer is preferably 50% or more.

As the host compound, a known host compound may be used alone, or a plurality of kinds of host compounds may be used. By using a plurality of kinds of host compounds, movement of charges can be adjusted, and efficiency of an organic EL element can be enhanced. Furthermore, by using a plurality of kinds of light-emitting materials described below, different kinds of light emission can be mixed, and any light emission color can be thereby obtained.

The host compound used for the light-emitting layer may be a conventionally known low molecular weight compound, a polymer compound having a repeating unit, or a low molecular weight compound having a polymerizable group such as a vinyl group or an epoxy group (vapor deposition polymerizable light-emitting host).

Examples of the host compound applicable to the present invention include compounds described in JP 2001-257076 A, JP 2001-357977 A, JP 2002-8860 A, JP 2002-43056 A, JP 2002-105445 A, JP 2002-352957 A, JP 2002-231453 A, JP 2002-234888 A, JP 2002-260861 A, JP 2002-305083 A, US 2005/0112407 A, US 2009/0030202 A, WO 2001/039234 A, WO 2008/056746 A, WO 2005/089025 A, WO 2007/063754 A, WO 2005/030900 A, WO 2009/086028 A, WO 2012/023947 A, JP 2007-254297 A, and EP 2034538 B.

<Light-Emitting Material>

Examples of a light-emitting material that can be used in the present invention include a phosphorescence emission compound (also referred to as a phosphorescent compound, a phosphorescence emission material, or a phosphorescence emission dopant) and a fluorescence emission compound (also referred to as a fluorescent compound or a fluorescence emission material). However, a phosphorescence emission compound is particularly preferably used from a viewpoint of being able to obtain high luminous efficiency.

<Phosphorescence Emission Compound>

The phosphorescence emission compound is a compound in which light emission from an excited triplet is observed, and is specifically defined as a compound that emits phosphorescence at room temperature (25° C.) and has a phosphorescence quantum yield of 0.01 or more at 25° C. However, the phosphorescence quantum yield is preferably 0.1 or more.

The phosphorescence quantum yield can be measured by a method described in Spectroscopy II of the fourth edition of Experimental Chemistry Course 7, p. 398 (1992 edition, Maruzen). The phosphorescence quantum yield in a solution can be measured using various solvents. However, in a case where a phosphorescence emission compound is used in the present invention, it is only required to achieve the phosphorescence quantum yield of 0.01 or more in any solvent.

The phosphorescence emission compound can be appropriately selected from known compounds used for a light-emitting layer of a general organic EL element to be used. However, a complex-based compound containing a metal of groups 8 to 10 in the periodic table is preferable. An iridium compound, an osmium compound, a platinum compound (platinum complex-based compound), and a rare earth complex are more preferable. An iridium compound is the most preferable among these compounds.

In the present invention, at least one light-emitting layer may contain two or more kinds of phosphorescence emission compounds, and a concentration ratio of the phosphorescence emission compounds in the light-emitting layer may vary in a thickness direction of the light-emitting layer.

Specific examples of the known phosphorescence emission compound that can be used in the present invention include compounds described in the following literatures.

Examples of the phosphorescence emission compound include compounds described in Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991 A, WO 2008/101842 A, WO 2003/040257 A, U.S. 2006/835469 A, U.S. 2006/0202194 A, U.S. 2007/0087321 A, and US 2005/0244673 A.

Examples of the phosphorescence emission compound further include compounds described in Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290 A, WO 2009/000673 A, U.S. Pat. No. 7,332,232, US 2009/0039776 A, U.S. Pat. No. 6,687,266, US 2006/0008670 A, US 2008/0015355 A, U.S. Pat. No. 7,396,598, US 2003/0138657 A, and U.S. Pat. No. 7,090,928.

Examples of the phosphorescence emission compound further include compounds described in Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2006/056418 A, WO 2005/123873 A, WO 2005/123873 A, WO 2006/082742 A, U.S. 2005/0260441 A, U.S. Pat. No. 7,534,505, U.S. 2007/0190359 A, U.S. Pat. No. 7,338,722, U.S. Pat. No. 7,279,704, and U.S. 2006/103874 A.

Examples of the phosphorescence emission compound further include compounds described in WO 2005/076380 A, WO 2008/140115 A, WO 2011/134013 A, WO 2010/086089 A, WO 2012/020327 A, WO 2011/051404 A, WO 2011/073149 A, JP 2009-114086 A, JP 2003-81988 A, and JP 2002-363552 A.

In the present invention, preferable examples of the phosphorescence emission compound include an organometallic complex having Ir as a central metal. A complex containing at least one coordination mode of a metal-carbon bond, a metal-nitrogen bond, a metal-oxygen bond, and a metal-sulfur bond is more preferable.

The phosphorescence emission compound described above (also referred to as a phosphorescence emission metal complex) can be synthesized by applying methods disclosed in, for example, Organic Letter, vol. 3, No. 16, pp. 2579 to 2581 (2001), Inorganic Chemistry, vol. 30, No. 8, pp. 1685 to 1687 (1991), J. Am. Chem. Soc., vol. 123, p. 4304 (2001), Inorganic Chemistry, vol. 40, No. 7, pp. 1704 to 1711 (2001), Inorganic Chemistry, vol. 41, No. 12, pp. 3055 to 3066 (2002), New Journal of Chemistry., vol. 26, p. 1171 (2002), European Journal of Organic Chemistry, vol. 4, pp. 695 to 709 (2004), and reference literatures and the like described in these literatures.

<Fluorescence Emission Compound>

Examples of the fluorescence emission compound include a coumarin-based dye, a pyran-based dye, a cyanine-based dye, a croconium-based dye, a squarylium-based dye, an oxobenzanthracene-based dye, a fluorescein-based dye, a rhodamine-based dye, a pyrylium-based dye, a perylene-based dye, a stilbene-based dye, a polythiophene-based dye, and a rare earth complex-based phosphor.

[Carrier Transport Functional Layer Group]

Next, a charge injection layer, a hole transport layer, an electron transport layer, and a blocking layer will be described in this order as typical examples of layers constituting the carrier transport functional layer group.

(Charge Injection Layer)

The charge injection layer is a layer disposed between an electrode and a light-emitting layer in order to lower a driving voltage or enhance light emission luminance. Details of the charge injection layer are described in Part 2, Chapter 2, “Electrode Material” (pp. 123 to 166) of “Organic EL element and Frontiers of Industrialization Thereof (issued by NTS Inc. on Nov. 30, 1998). The charge injection layer includes a hole injection layer and an electron injection layer.

As the charge injection layer, generally, a hole injection layer can be present between a positive electrode and a light-emitting layer or a hole transport layer, and an electron injection layer can be present between a negative electrode and a light-emitting layer or an electron transport layer. However, in the present invention, the charge injection layer is preferably disposed so as to be adjacent to a light-transmissive electrode. In a case where the charge injection layer is used in an intermediate electrode, at least one of an adjacent electron injection layer and hole injection layer only needs to satisfy requirements of the present invention.

The hole injection layer is a layer disposed so as to be adjacent to a positive electrode which is a light-transmissive electrode in order to lower a driving voltage or enhance light emission luminance. Details of the hole injection layer are described in Part 2, Chapter 2, “Electrode Material” (pp. 123 to 166) of “Organic EL element and Frontiers of Industrialization Thereof (issued by NTS Inc. on Nov. 30, 1998).

Details of the hole injection layer are also described in JP 9-45479 A, JP 9-260062 A, JP 8-288069 A, and the like. Examples of a material used for the hole injection layer include a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolecarbazole derivative, an isoindole derivative, an acene-based derivative such as anthracene or naphthalene, a fluorene derivative, a fluorenone derivative, polyvinyl carbazole, a polymer material or an oligomer having an aromatic amine introduced into a main chain or a side chain thereof, a polysilane, and a conductive polymer or oligomer (for example, PEDOT (polyethylene dioxythiophene): PSS (polystyrene sulfonic acid), an aniline-based copolymer, polyaniline, or polythiophene).

Examples of the triarylamine derivative include a benzidine type compound typified by α-NPD (4,4′-bis[N-(1-naphthyl)-N-phenylamino] biphenyl), a starburst type compound typified by MTDATA (4,4′,4″-tris[N-(3-methylphenyl)-N-phenylamino] triphenylamine), and a compound having fluorene or anthracene in a triarylamine-linked core part.

In addition, a hexaazatriphenylene derivative described in JP 2003-519432 A, JP 2006-135145 A, and the like can also be used as a hole transport material similarly.

The electron injection layer is a layer disposed between a negative electrode and a light-emitting layer in order to lower a driving voltage or enhance light emission luminance. In a case where the negative electrode is constituted by the light-transmissive electrode according to the present invention, the electron injection layer is disposed so as to be adjacent to the light-transmissive electrode. Details of the electron injection layer are described in Part 2, Chapter 2, “Electrode Material” (pp. 123 to 166) of “Organic EL element and Frontiers of Industrialization Thereof (issued by NTS Inc. on Nov. 30, 1998).

Details of the electron injection layer are also described in JP 6-325871 A, JP 9-17574 A, JP 10-74586 A, and the like. Specific examples of a material preferably used for the electron injection layer include a metal typified by strontium or aluminum, an alkali metal compound typified by lithium fluoride, sodium fluoride, or potassium fluoride, an alkali metal halide layer typified by magnesium fluoride or calcium fluoride, an alkaline earth metal compound layer typified by magnesium fluoride, a metal oxide typified by molybdenum oxide or aluminum oxide, and a metal complex typified by lithium 8-hydroxyquinolate (Liq). In a case where the light-transmissive electrode in the present invention is a negative electrode, an organic material such as a metal complex is particularly preferably used. The electron injection layer is desirably a very thin film, and the layer thickness of the electron injection layer is preferably within a range of 1 nm to 10 μm although depending on a constituent material.

(Hole Transport Layer)

The hole transport layer is formed of a hole transport material having a function of transporting holes. In a broad sense, each of the hole injection layer and the electron blocking layer also functions as a hole transport layer. A single hole transport layer or a plurality of hole transport layers can be disposed.

The hole transport material has any one of a hole injection property, a hole transport property, and an electron barrier property, and may be either an organic substance or an inorganic substance. Examples of the hole transport material include a triazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline-based copolymer, a conductive polymer oligomer, and a thiophene oligomer.

As the hole transport material, the compounds described above can be used. However, a porphyrin compound, an aromatic tertiary amine compound, and a styrylamine compound can be used, and an aromatic tertiary amine compound is particularly preferably used.

Typical examples of the aromatic tertiary amine compound and the styrylamine compound include N,N,N′,N′-tetraphenyl-4,4′-diaminophenyl, N,N′-diphenyl-N,N-bis(3-methylphenyl)-[1,1′-biphenyl]-4,4′-diamine (abbreviation: TPD), 2,2-bis(4-di-p-tolylaminophenyl) propane, 1,1-bis(4-di-p-tolylaminophenyl) cyclohexane, N,N,N′,N′-tetra-p-tolyl-4,4′-diaminobiphenyl, 1,1-bis(4-di-p-tolylaminophenyl)-4-phenylcyclohexane, bis(4-dimethylamino-2-methylphenyl) phenylmethane, bis(4-di-p-tolylaminophenyl) phenylmethane, N,N′-diphenyl-N,N′-di(4-methoxyphenyl)-4,4′-diaminobiphenyl, N,N,N′,N′-tetraphenyl-4,4′-diaminodiphenyl ether, 4,4′-bis(diphenylamino) quadriphenyl, N,N,N-trip-tolyl) amine, 4-(di-p-tolylamino)-4′-[4-(di-p-tolylamino) styryl] stilbene, 4-N,N-diphenylamino-(2-diphenylvinyl) benzene, 3-methoxy-4′-N,N-diphenylaminostylbenzene, and N-phenylcarbazole.

The hole transport layer can be formed by forming a thin film of the above hole transport material by a known method such as a vacuum vapor deposition method, a spin coating method, a casting method, a printing method including an inkjet method, or a Langmuir Blodgett method (LB method). The layer thickness of the hole transport layer is not particularly limited, but is usually within a range of about 5 nm to 5 μm, and preferably within a range of 5 to 200 nm. The hole transport layer may have a single layer structure formed of one or more of the above materials.

Furthermore, by doping a material of the hole transport layer with an impurity, a p-property can also be increased. Examples thereof are described in JP 4-297076 A, JP 2000-196140 A, JP 2001-102175 A, and J. Appl. Phys., 95, 5773 (2004).

As described above, a higher p-property of the hole transport layer is preferable because an element with lower power consumption can be manufactured.

(Electron Transport Layer)

The electron transport layer is formed of a material having a function of transporting electrons. In a broad sense, the electron transport layer includes an electron injection layer and a hole blocking layer. The electron transport layer can be disposed as a single layer structure or a laminated structure of a plurality of layers.

In an electron transport layer having a single layer structure and an electron transport layer having a laminated structure, an electron transport material (also serving as a hole blocking material) constituting a layer portion adjacent to a light-emitting layer only needs to have a function of transporting electrons injected from a cathode to the light-emitting layer. As such a material, any compound can be selected to be used from conventionally known compounds. Examples thereof include a nitro-substituted fluorene derivative, a diphenylquinone derivative, a thiopyran dioxide derivative, carbodiimide, a fluorenylidenemethane derivative, anthraquinodimethane, an anthrone derivative, and an oxadiazole derivative. Furthermore, in the above oxadiazole derivative, a thiadiazole derivative in which an oxygen atom of an oxadiazole ring is replaced with a sulfur atom, and a quinoxaline derivative having a quinoxaline ring known as an electron withdrawing group can be also used as a material of the electron transport layer. Furthermore, a polymer material obtained by introducing these materials into a polymer chain, or a polymer material using these materials as a main chain of a polymer can also be used.

Furthermore, a metal complex of a 8-quinolinol derivative, such as tris(8-quinolinol) aluminum (abbreviation: Alq3), tris(5,7-dichloro-8-quinolinol) aluminum, tris(5,7-dibromo-8-quinolinol) aluminum, tris(2-methyl-8-quinolinol) aluminum, tris(5-methyl-8-quinolinol) aluminum, or bis(8-quinolinol) zinc (abbreviation: Znq), and a metal complex in which a central metal of each of these complexes is replaced with In, Mg, Cu, Ca, Sn, Ga, or Pb can also be used as a material of the electron transport layer.

The electron transport layer can be formed by forming a thin film of the above material by a known method such as a vacuum vapor deposition method, a spin coating method, a casting method, a printing method including an inkjet method, or an LB method. The layer thickness of the electron transport layer is not particularly limited, but is usually within a range of about 5 nm to 5 μm, and preferably within a range of 5 to 200 nm. The electron transport layer may have a single layer structure formed of one or more kinds of the above materials.

(Blocking Layer)

Examples of the blocking layer include a hole blocking layer and an electron blocking layer. The blocking layer is a layer disposed as necessary in addition to the constituent layers of the carrier transport functional layer unit 3 described above. Examples of the blocking layer include hole blocking layers described in JP 11-204258 A, JP 11-204359 A, and “Organic EL element and Frontiers of Industrialization Thereof, p. 237 (issued by NTS Inc. on Nov. 30, 1998)”.

In a broad sense, the hole blocking layer has a function of an electron transport layer. The hole blocking layer is formed of a hole blocking material having a function of transporting electrons and having an extremely small ability to transport holes, and can improve a probability of recombining an electron and a hole by blocking holes while transporting electrons. Furthermore, the configuration of the electron transport layer can be also used as the hole blocking layer as required. The hole blocking layer is preferably disposed so as to be adjacent to a light-emitting layer.

Meanwhile, the electron blocking layer has a function of a hole transport layer in a broad sense. The electron blocking layer is formed of a material having a function of transporting holes and having an extremely small ability to transport electrons, and can improve a probability of recombining an electron and a hole by blocking electrons while transporting holes. Furthermore, the configuration of the hole transport layer can be also used as the electron blocking layer as required. The layer thickness of the hole blocking layer applied to the present invention is preferably within a range of 3 to 100 nm, and more preferably within a range of 5 to 30 nm.

[Second Electrode: Light-Transmissive Negative Electrode]

The negative electrode constituted by being divided by a separator according to the present invention is a light-transmissive electrode that functions in order to supply holes to the carrier transport functional layer group or the light-emitting layer. Examples of the negative electrode include a metal, an alloy, an organic or inorganic conductive compound, and a mixture thereof. Examples thereof include gold, aluminum, silver, magnesium, lithium, a magnesium/copper mixture, a magnesium/silver mixture, a magnesium/aluminum mixture, a magnesium/indium mixture, indium, a lithium/aluminum mixture, a rare earth metal, and an oxide semiconductor such as ITO, ZnO, TiO₂, or SnO₂. Among these materials, a configuration constituted by at least a thin film metal or alloy is preferable, and a configuration including a base layer formed using a nitrogen-containing compound and an electrode layer formed of silver or an alloy containing silver as a main component on the base layer is more preferable.

Examples of the silver or the alloy containing silver as a main component, preferably used as the light-transmissive negative electrode include similar materials to those described in the description of the positive electrode. Specifically, the negative electrode may be formed of silver alone or an alloy containing silver (Ag). Examples of such an alloy include silver.magnesium (Ag.Mg), silver.copper (Ag.Cu), silver.palladium (Ag.Pd), silver.palladium.copper (Ag.Pd.Cu), and silver.indium (Ag.In).

The negative electrode can be manufactured by forming thin films of these conductive materials by a method such as vapor deposition or sputtering. Furthermore, a sheet resistance as a second electrode is preferably several hundred Ω/sq. or less, and the film thickness is usually selected within a range of 5 nm to 5 μm, preferably within a range of 5 to 200 nm.

<<Basic Configuration of Organic EL Panel>>

Next, details of the organic EL panel of the present invention will be described.

The organic EL panel of the present invention is characterized by having a configuration in which the organic EL panel is divided into a plurality of light-emitting areas (organic EL elements), and a positive electrode constituting one of the divided light-emitting areas is electrically connected in series to a negative electrode constituting another adjacent light-emitting area.

Hereinafter, a basic configuration of the organic EL panel of the present invention having a plurality of divided light-emitting areas will be described.

### First Embodiment

FIG. 2 is a schematic cross-sectional view illustrating an example of a configuration of the organic EL panel of the present invention including a plurality of organic EL elements (first embodiment).

In the organic EL panel (P) illustrated in FIG. 2, among the constituent materials of the organic EL element (OLED) described above in FIG. 1, description of the gas barrier layer, the sealing adhesive layer, the sealing member, and the like is omitted.

In the organic EL panel (P) illustrated in FIG. 2, a plurality of organic EL elements (OLEDs) is arranged while being apart from one another on one light-transmissive substrate (1) having a wide area to form an independent light-emitting area. Specifically, a plurality of organic EL elements (OLEDs) constituted by a positive electrode (3), a separator (8), an organic functional layer unit (U), a negative electrode (7), and the like is arranged on the substrate (1). The negative electrode (7) is formed while being electrically divided between the two separators (8). A negative electrode (7) constituting one of the divided light-emitting areas is electrically connected in series to an end portion of a positive electrode (3) constituting another adjacent light-emitting area in a region indicated by a circular dashed line portion. With such a configuration, the plurality of organic EL elements (OLEDs) can be connected to one another in series.

In the configuration illustrated in FIG. 2, a region from a left end portion of the negative electrode (7) in contact with the separator (8) to a right end portion of the positive electrode (3) is a “light-emitting area”, and a region from the right end portion of the positive electrode (3) to a left end portion of a negative electrode (7) in contact with a separator (8) of another adjacent organic EL element (OLED) is a “non-light-emitting area”.

### Second Embodiment: Formation of Insulating Layer

In the organic EL panel (P) of the present invention, an insulating layer (12) is preferably disposed between a positive electrode (3) and a separator (8).

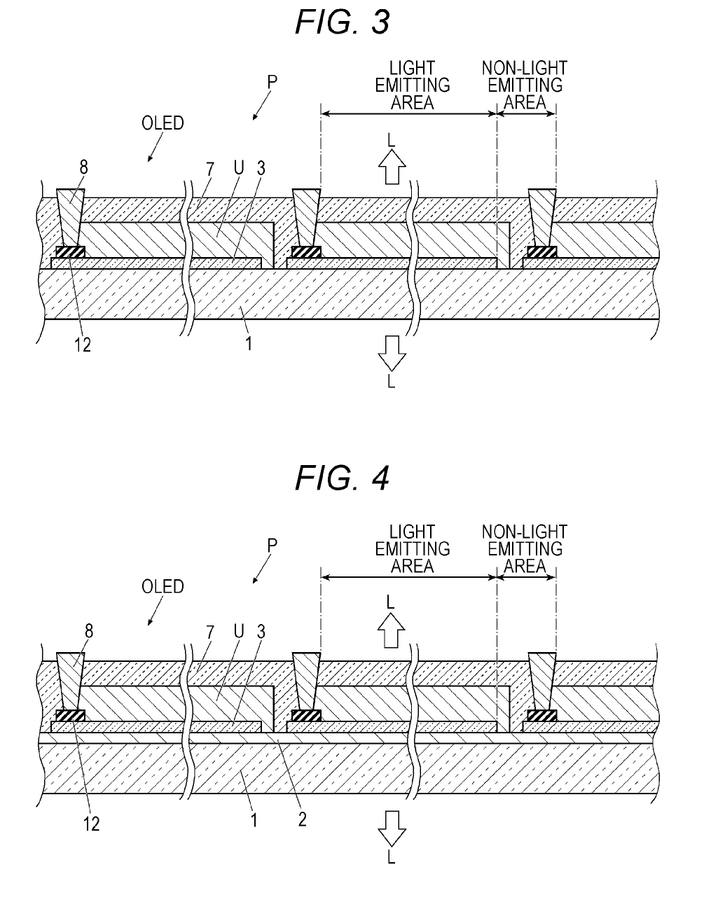

FIG. 3 is a schematic cross-sectional view exemplifying the configuration of the organic EL panel (P) of the present invention, having an insulating layer (12) (second embodiment).

The basic configuration is similar to that of the first embodiment described in FIG. 2, and has the insulating layer (12) between a positive electrode (3) and a separator (8). In this way, by disposing the insulating layer (12), it is possible to further enhance an insulating property between a positive electrode and a negative electrode in the same light-emitting area, to prevent a short circuit or the like, and to realize high light emission stability.

(Insulating Layer)

The insulating layer is preferably formed so as to cover an end portion of the positive electrode (3). The thickness of an organic functional layer unit (U) is thin at an end portion of a positive electrode. Therefore, it is possible to make occurrence of a short circuit difficult by forming the insulating layer. A portion where the insulating layer is formed can be a non-light-emitting region that does not contribute to light emission.

As a position where the insulating layer is formed, the insulating layer only needs to be formed such that a positive electrode is exposed in a light-emitting area. The size of a light-emitting region is not particularly limited, and is appropriately set according to application of the organic EL panel or the like.

Examples of a material for forming the insulating layer include a photocurable resin such as a photosensitive polyimide resin or an acrylic resin, a thermosetting resin, and an inorganic material.

As a method for forming the insulating layer, a general method such as a photolithography method or a printing method can be used. However, the insulating layer is particularly preferably formed by a photolithography method.

### Third Embodiment: Formation of Gas Barrier Layer on Substrate

The present invention preferably has a configuration in which a flexible resin substrate is used as a substrate and a gas barrier layer is disposed on the flexible resin substrate (third embodiment).

The organic EL panel (P) illustrated in FIG. 4 is illustrated in a schematic cross-sectional view exemplifying a configuration having a gas barrier layer (2) on a substrate (third embodiment).

A basic configuration is similar to the configuration described in FIG. 3 of the above second embodiment. However, a gas barrier layer (2) is formed between a substrate (1) and a positive electrode (3).

By disposing such a gas barrier layer (2), a higher order gas barrier property can be imparted to a flexible resin substrate having higher water vapor transmission rate or the like than a glass substrate as a substrate.

<Gas Barrier Layer>

By forming the light-transmissive gas barrier layer (2) on one surface or both surfaces of the substrate (1), at least on the entire surface on a side where a positive electrode (3, first electrode) is formed, it is possible to suppress invasion of a substance such as moisture or oxygen deteriorating a constituent material of an organic EL element.

The gas barrier layer (2) may be not only an inorganic material coating film but also a coating film formed of a composite material with an organic material or a hybrid coating film formed by laminating these coating films. As performance of the gas barrier layer (2), the gas barrier layer (2) is preferably a light-transmissive insulating film having such a gas barrier property that a water vapor transmission rate (environmental condition: 25±0.5° C., relative humidity: 90±2%) measured by a method in accordance with JIS (Japanese Industrial Standards)-K7129 (2008) is about 0.01 g/m²·24 h or less, an oxygen transmission rate measured by a method in accordance with JIS-K7126 (2006) is about 0.01 ml/m²·24 h. atm or less, resistivity is 1×10¹² Ω·cm or more, and light transmittance is about 80% or more in a visible light region.

As a material for forming the gas barrier layer (2), any material can be used as long as being able to suppress invasion of water or a gas such as oxygen deteriorating an organic EL element into the organic EL element.

The gas barrier layer (2) can be formed of a coating film formed of an inorganic material such as silicon oxide, silicon nitride, silicon oxynitride, silicon carbide, silicon oxycarbide, aluminum oxide, aluminum nitride, titanium oxide, zirconium oxide, niobium oxide, or molybdenum oxide, and preferably contains a silicon compound such as silicon nitride or silicon oxide as a main raw material.

As a method for forming the gas barrier layer, a conventionally known thin film forming method can be appropriately selected to be used. Examples of the method include a vacuum vapor deposition method, a sputtering method, a magnetron sputtering method, a molecular beam epitaxy method, a cluster ion beam method, an ion plating method, a plasma polymerization method, an atmospheric pressure plasma polymerization method (refer to JP 2004-68143 A), a plasma chemical vapor deposition (CVD) method, a laser CVD method, a thermal CVD method, and an atomic layer deposition (ALD) method. Furthermore, a wet application method using polysilazane or the like can be applied.

### Fourth Embodiment: Arrangement Pattern of Organic EL Elements

In the organic EL panel of the present invention having a plurality of independent light-emitting areas (organic EL elements), a pattern in which a plurality of light-emitting areas is arranged in parallel in stripes is preferable.

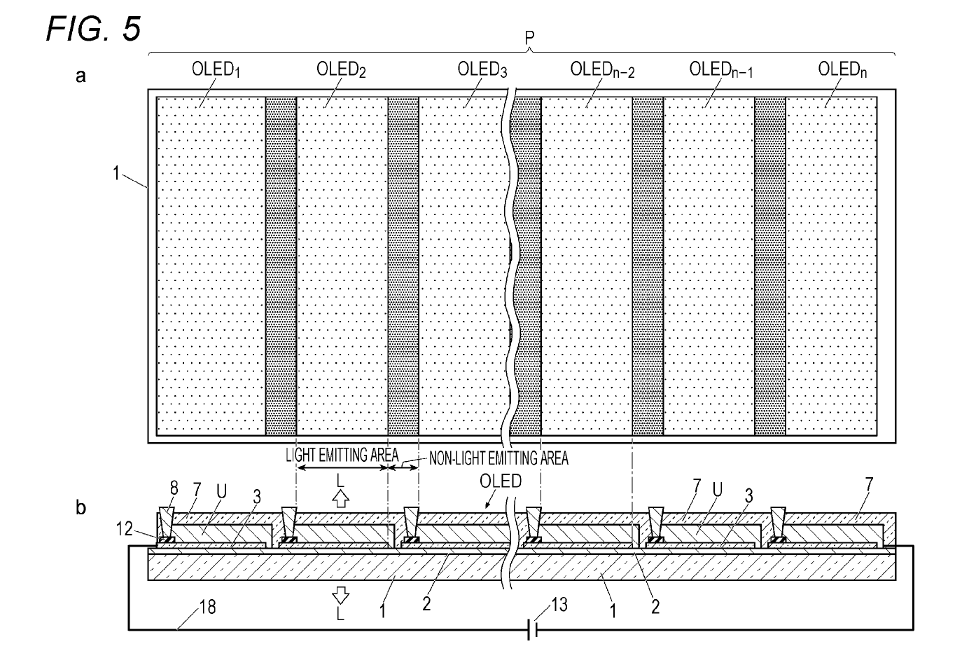

FIG. 5 illustrates a top view and a schematic cross-sectional view of an organic EL panel having a plurality of light-emitting areas arranged in stripes (fourth embodiment).

In the configuration illustrated in (a) of FIG. 5, an example in which light-emitting areas constituted by strip-shaped organic EL elements (OLEDs) are arranged in stripes on a substrate (1) having a large area is illustrated. In (a) of FIG. 5, as the organic EL elements (OLEDs), n OLEDs of OLED₁ to OLEDₙ are arranged in parallel. In a case where OLEDs are arranged in stripes on the same plane, the number of OLEDs arranged cannot be unconditionally determined depending on the size of a substrate and the size of the OLED. However, the minimum configuration is a configuration using two OLEDs, and the number of OLEDs is preferably within a range of 2 to 20, and more preferably within a range of 2 to 10 from a viewpoint of achieving luminance uniformity of the invention of the present application. Therefore, as an example, in a large area organic EL panel having a substrate width of 10 cm×10 cm, the size of a light-emitting area by an OLED is within a range of 0.5 cm in width×10 cm in length to 5 cm in width×10 cm in length, and preferably within a range of 1.0 cm in width×10 cm in length to 5 cm in width×10 cm in length. However, these light-emitting areas can be appropriately selected according to the size of a substrate and the number of OLEDs arranged.

Furthermore, the width of a “non-light-emitting area” illustrated in FIG. 5 is preferably within a range of approximately 0.2 to 1.0 mm.

(b) of FIG. 5 is a schematic cross-sectional view of the organic EL panel (P) having the configuration illustrated in (a) of FIG. 5. In an organic EL element (OLED) group in which n OLEDs of OLED₁ to OLEDₙ are arranged in parallel, an end portion of a positive electrode (3) constituting one of the divided light-emitting areas is electrically connected in series to an end portion of a negative electrode (7) constituting another adjacent light-emitting area. Furthermore, a positive electrode (3) of an OLED (for example, OLED₁ at a left end portion illustrated in (b) of FIG. 5) arranged at one end portion is connected to a negative electrode (7) of an OLED (for example, OLEDₙ at a right end portion illustrated in (b) of FIG. 5) arranged at the other end portion through wiring (18). An application power supply (13) is disposed in a circuit thereof, and supplies electric power for causing each OLED to emit light.

[Schematic Circuit Diagram of Organic EL Panel]

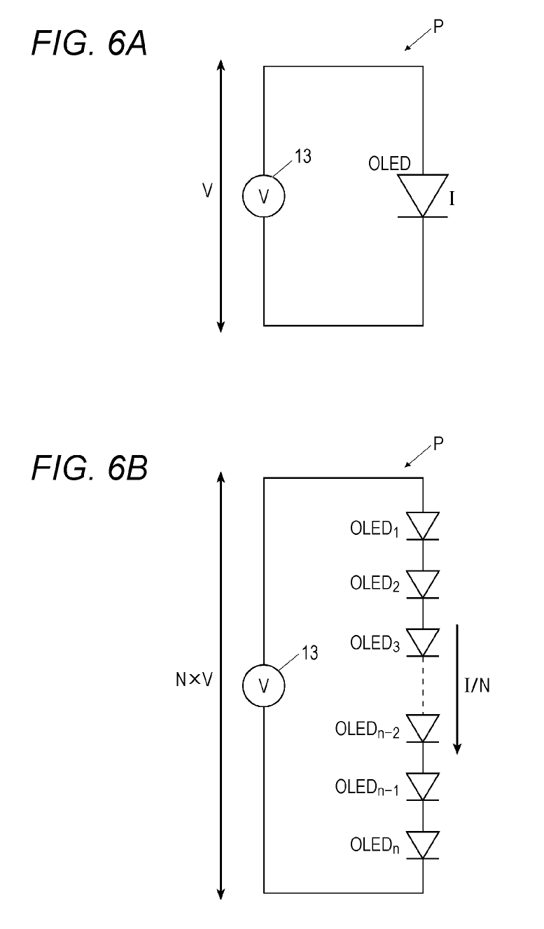

FIG. 6A illustrates a circuit diagram of a conventional organic EL panel. FIG. 6B illustrates a circuit diagram of the organic EL panel of the present invention.

FIG. 6A is a circuit diagram of a conventional organic EL panel (P), constituted by a single large-sized organic EL element (OLED), and light is emitted by applying a voltage V and a current I to the organic EL element from an application power supply (13). However, in this configuration, a large capacity current I flows through a wide area of the OLED. Therefore, a region where a large amount of current flows and a region where only a small amount of current flows are generated on a surface of the organic EL element, and luminance unevenness easily occurs. Luminance of the organic EL element is higher as a flowing current is larger. Therefore, generation of such a difference in current easily causes luminance unevenness.

Meanwhile, in the circuit diagram illustrated in FIG. 6B, in the organic EL panel (P) of the present invention in which a plurality of OLEDs (OLED₁ to OLEDₙ) is arranged in parallel, light is emitted by applying a voltage N×V and a current I to the organic EL elements from an application power supply (13). However, a current flowing through each of the organic EL elements (OLEDs) is I/N, and a difference in current is hardly generated between the organic EL elements. Therefore, luminance unevenness hardly occurs, and therefore a large-sized organic EL panel having excellent light emission uniformity can be realized.

### Fifth Embodiment: Organic EL Element Including Sealing Member

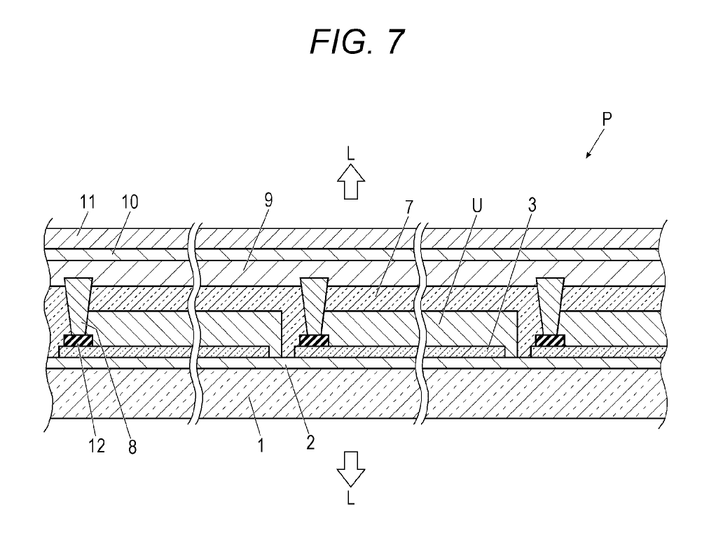

FIG. 7 is a schematic cross-sectional view exemplifying the configuration of the organic EL panel of the present invention, including a sealing member (fifth embodiment).

In the organic EL panel (P) illustrated in FIG. 7, an example in which a sealing member is further formed on the organic EL panel (P) including a plurality of organic EL elements (OLEDs), formed up to the negative electrode, described above, illustrated in FIG. 4, is illustrated.

As illustrated in FIG. 7, a sealing adhesive (9) is applied onto the entire surface of the plurality of organic EL elements (OLEDs), and then a sealing member (11) including a gas barrier layer (10) is formed on an outermost surface.

It is only required to dispose the sealing member so as to cover display regions of the organic EL elements, and the sealing member may have a recessed plate shape or a flat plate shape. Furthermore, an electrical insulation property is not particularly limited as long as the sealing member has transparency.

Specific examples of the sealing member include a flexible and light-transmissive glass substrate, resin substrate, film, and metal film (metal foil). Particular examples of the glass substrate include soda-lime glass, barium/strontium-containing glass, lead glass, aluminosilicate glass, borosilicate glass, barium borosilicate glass, and quartz. Examples of the resin substrate include polycarbonate, an acrylic resin, polyethylene terephthalate, polyethersulfide, and polysulfone.

As the sealing adhesive, a polyurethane-based adhesive, a polyester-based adhesive, an epoxy-based adhesive, an acrylic adhesive, or the like can be used. A curing agent may be used in combination as necessary. A hot melt lamination method, an extrusion lamination method, and a coextrusion lamination method can be used, but a dry lamination method is preferable.

In the present invention, a resin substrate and a crow substrate can be preferably used as a sealing member from a viewpoint of being able to form a thin film of the organic EL element. Furthermore, the resin substrate preferably has a water vapor transmission rate of 1×10⁻³ g/m²·24 h or less at a temperature of 25±0.5° C. and a relative humidity of 90±2% RH, measured by a method in accordance with JIS K 7129-1992, and more preferably has an oxygen transmission rate of 1×10⁻³ ml/m²·24 h. atm (1 atm is 1.01325×10⁵ Pa) or less, measured by a method in accordance with JIS K 7126-1987, and a water vapor transmission rate of 1×10⁻³ g/m²·.24 h or less at a temperature of 25±0.5° C. and a relative humidity of 90±2% RH. In order to satisfy this condition, a gas barrier layer similar to that described for the above substrate is preferably disposed.

An inert gas such as nitrogen or argon, or an inert liquid such as fluorohydrocarbon or silicone oil can be injected into a gap between a sealing member and a display region (light-emitting region) of an organic EL element as a gas phase or a liquid phase. Furthermore, a gap between a sealing member and a display region of an organic EL element can be in a vacuum state, or a hygroscopic compound can be enclosed in the gap.

### Method for Manufacturing Organic EL Panel: Sixth Embodiment

Next, an outline of a method for manufacturing the organic EL panel of the present invention will be described.

The method for manufacturing the organic E panel of the present invention is a method for manufacturing an organic EL panel including an organic electroluminescence element having a light transmittance of 50% or more at a wavelength of 550 nm during non-emission of light, having the configuration described above, and is characterized in that, in the organic electroluminescence element, a light-emitting area constituted by at least a positive electrode, an organic functional layer unit, and a negative electrode is formed on a substrate while being divided into a plurality of parts, a pattern in which the negative electrode is separated by a separator disposed on the positive electrode is formed, a positive electrode constituting one of the divided light-emitting areas is electrically connected in series to a negative electrode constituting another adjacent light-emitting area, and the positive electrode, the negative electrode, and the separator are formed by a photolithography method.

In addition, a method for manufacturing an insulating layer between the positive electrode and the separator by a photolithography method is preferable.

A process of forming each constituent member of a typical organic EL panel (P) is as follows. That is, a gas barrier layer (2) is formed on a substrate (1) by a vacuum vapor deposition method, a sputtering method, a CVD method, or a wet application method. Thereafter, a positive electrode (3), an insulating layer (12), and a separator (8) are formed by a photolithography method. Thereafter, an organic functional layer unit (U) and a negative electrode (7) are formed by a vapor deposition method. Finally, a sealing adhesive (9) is formed by a wet application method or the like, and then the entire surface is sealed with a sealing substrate (11) having a gas barrier layer (10) to manufacture an organic EL panel (P).

(Photolithography Method)

In the present invention, a positive electrode (3), an insulating layer (12), and a separator (8) of a desired pattern can be formed by etching processing (patterning) using a photolithography method. By applying the photolithography method to the above formation, the high definition positive electrode (3), insulating layer (12), and separator (8) can be formed with high precision, and an extremely narrow non-light-emitting area can be formed.

The photolithography method applicable to the present invention is a method in which a positive electrode (3), an insulating layer (12), and a separator (8) are formed in a desired high definition pattern through steps of resist application, (preheating) exposure, development, rinse, (pretreatment), etching, and resist peeling. In the present invention, a conventionally known general photolithography method can be appropriately used. For example, methods described in JP 2010-145532 A, JP 2012-118425 A, JP 2013-25447 A, and JP 2013-25448 A can be referred to.

In the photolithography method, for example, either a positive type resist or a negative type resist can be used as a resist. After a resist is applied, preheating or prebaking can be performed as necessary. Upon exposure, a pattern mask having a desired pattern is disposed, and it is only required to irradiate the resist with light having a wavelength suitable for the resist used, generally ultraviolet light, from above the pattern mask. After exposure, development can be performed with a developing solution suitable for the resist used. After development, the development is stopped with a rinsing liquid such as water, cleaning is performed, and a resist pattern is thereby formed.

Subsequently, the formed resist pattern is subjected to pretreatment or postbaking as necessary, and then can be engraved by etching. After etching, the remaining resist is peeled off, and a positive electrode (3), an insulating layer (12), and a separator (8) having a desired pattern are obtained. As described above, the photolithography method applied to the present invention is a method generally recognized by a person skilled in the art, and a person skilled in the art can easily select a specific application mode thereof according to a purpose.

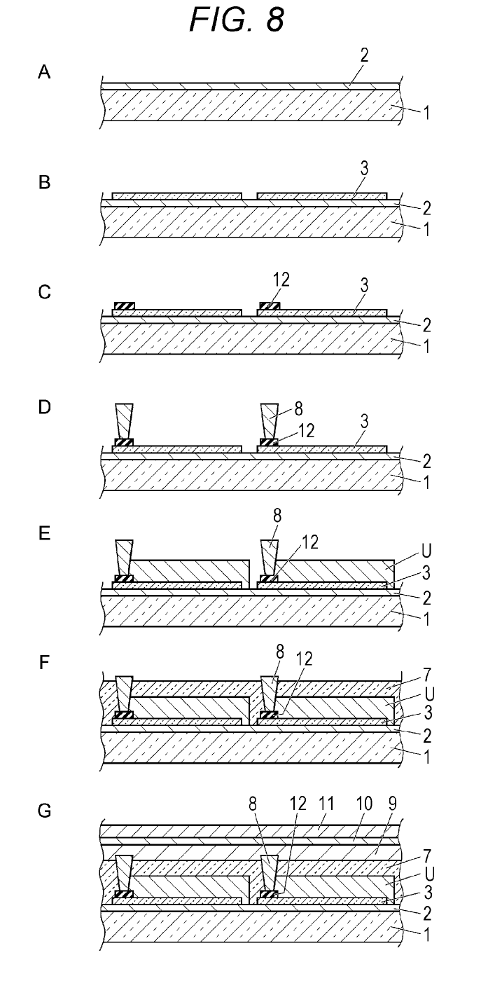

FIG. 8 is a process flow diagram exemplifying procedures for manufacturing the organic EL panel (P) of the fifth embodiment illustrated in FIG. 7. (sixth embodiment)

First, as illustrated in (a) of FIG. 8, a gas barrier layer (2) is formed on a light-transmissive substrate (1). As a method for forming the gas barrier layer (2), as described above, the gas barrier layer (2) is formed using a vacuum vapor deposition method, a sputtering method, a magnetron sputtering method, a molecular beam epitaxy method, a cluster ion beam method, an ion plating method, a plasma polymerization method, an atmospheric pressure plasma polymerization method, a plasma CVD method, or a wet application method using polysilazane or the like.

Subsequently, as illustrated in (b) of FIG. 8, a plurality of light-transmissive positive electrodes (3) is formed while being apart from one another at predetermined positions on the gas barrier layer (2) using a photolithography method.

Subsequently, as illustrated in (c) of FIG. 8, an insulating layer (12) is formed in a specific area (end portion) on the positive electrode using a photolithography method.

Subsequently, as illustrated in (d) of FIG. 8, a separator (8) is formed on the formed insulating layer (12) using a photolithography method.

Subsequently, as illustrated in (e) of FIG. 8, a plurality of organic functional layer units (U) each including, for example, a carrier transport functional layer group 1 (4, for example, a hole injection layer or a hole transport layer), a light-emitting layer (5), and a carrier transport functional layer group 2 (6, an electron transport layer or the like) is formed.

For forming the layers constituting the organic functional layer unit, a spin coating method, a casting method, an inkjet method, a vapor deposition method, a printing method, and the like are used. However, a vapor deposition method using a fine mask (M) is preferably applied because a homogeneous layer is easily obtained and a film can be formed with high precision. Specifically, a heating boat for vapor deposition is filled with raw materials for forming each organic functional layer unit, the heating boat is heated, and patterns of the layers of the organic functional layer unit (U) are formed on the light-transmissive positive electrode (3) via a fine mask.

At this time, a formation method applied may be different among the layers constituting the organic functional layer unit layer (U). In a case of adopting a vapor deposition method for forming these layers, vapor deposition conditions therefor depend on the kind of a compound used or the like. However, in general, the conditions are desirably selected appropriately while a boat heating temperature is within a range of 50 to 450° C., the degree of vacuum is within a range of 1×10⁻⁶ to 1×10⁻² Pa, a deposition rate is within a range of 0.01 to 50 nm/sec, a substrate temperature is within a range of −50 to 300° C., and a layer thickness is within a range of 0.1 to 5 μm.

Subsequently, as illustrated in (f) of FIG. 8, a light-transmissive negative electrode (7) is formed on the entire surface of a specific area separated by the two separators (8) on the plurality of organic functional layer units (U). At this time, the negative electrode (7) Is formed so as to be electrically connected to an end portion of the positive electrode (3) of one adjacent organic EL element via a conductive adhesive or the like. Specifically, a heating boat for vapor deposition is filled with a raw material for forming a negative electrode, the heating boat is heated, and a negative electrode (7) is formed on an organic functional layer unit (U) and an adjacent positive electrode (3) via a fine mask. At this time, the negative electrode (7) is electrically connected to the adjacent positive electrode (3) by a conductive adhesive (not illustrated).

Subsequently, as illustrated in (g) of FIG. 8, after forming the negative electrode (7), the entire surface of the light-transmissive substrate (1), the gas barrier layer (2), the positive electrode (3), the insulating layer (12), the separator (8), the organic functional layer unit (U), and the negative electrode (7) is sealed with a sealing member (11) having a sealing resin layer (9) and a gas barrier layer (10).

### Seventh Embodiment: Formation of Negative Electrode with Thin Film Silver Layer

In the present invention, the light-transmissive negative electrode preferably includes a base layer formed using a nitrogen-containing compound and a thin film silver layer (negative electrode) formed of silver or an alloy containing silver as a main component on the base layer.

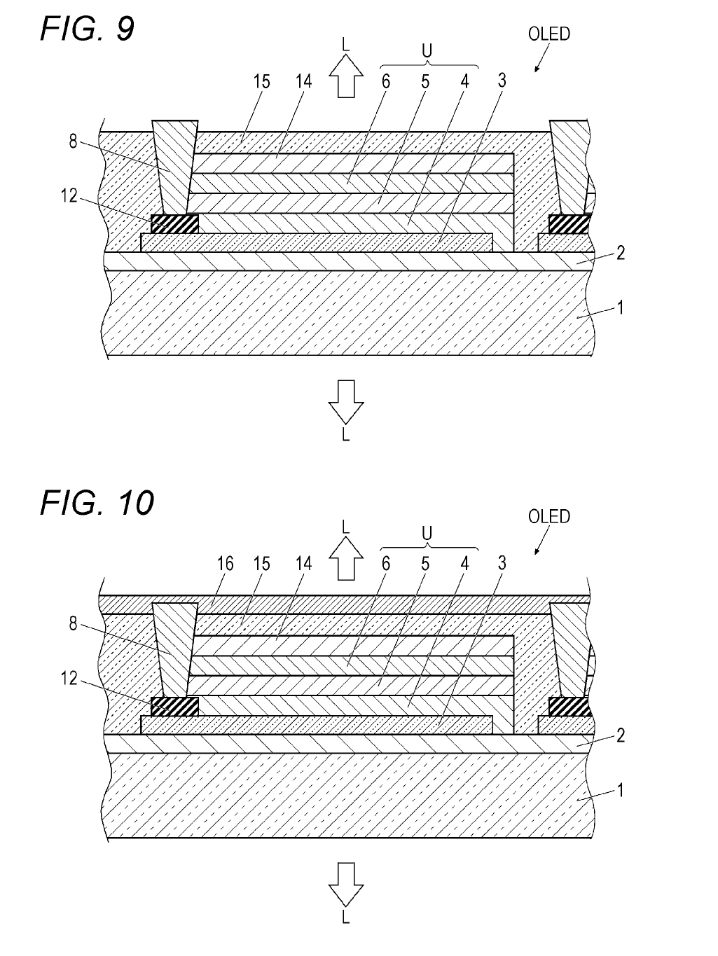

FIG. 9 illustrates a configuration including a base layer (14) and a thin film silver layer (15) formed of silver or an alloy containing silver as a main component disposed on the base layer (14) as a negative electrode.

By adopting the configuration illustrated in FIG. 9, when a negative electrode including silver or an alloy containing silver as a main component is formed on a base layer, a silver atom constituting the negative electrode interacts with a nitrogen atom-containing compound contained in the base layer. A diffusion distance of the silver atom on a surface of the base layer thereby decreases, aggregation of the silver atoms at specific positions can be suppressed, and a homogeneous thin film silver layer (15) can be obtained.

That is, a film of silver atoms is formed by single layer growth type (Frank-vander Merwe: FM type) film growth in which silver atoms first form a two-dimensional nucleus on a surface of a base layer containing a nitrogen atom-containing compound, more specifically, an asymmetric nitrogen atom-containing compound having an unshared electron pair not involved in aromaticity having an affinity for the silver atoms, and form a two-dimensional monocrystalline layer around the two-dimensional nucleus. A thin silver film with high homogeneity can be formed.

(Base Layer)

A material constituting the base layer is not particularly limited. Examples of the material include a nitrogen atom-containing compound capable of suppressing aggregation of silver which is a constituent material of a negative electrode formed on the base layer.

The nitrogen atom-containing compound that can be used for forming the base layer (14) is not particularly limited as long as containing a nitrogen atom in a molecule thereof, but a heterocyclic ring-containing compound having a nitrogen atom as a hetero atom is preferable. Examples of the heterocyclic ring having a nitrogen atom as a hetero atom include aziridine, azirine, azetidine, azeto, azolidine, azole, azinane, pyridine, azepane, azepine, imidazole, pyrazole, oxazole, thiazole, imidazoline, pyrazine, morpholine, thiazine, indole, isoindole, benzimidazole, purine, quinoline, isoquinoline, quinoxaline, cinnoline, pteridine, acridine, carbazole, benzo-C-cinnoline, porphyrin, chlorin, and choline.

Furthermore, the nitrogen atom-containing compound contained in the base layer (14) is preferably an aromatic heterocyclic compound having a nitrogen atom having an unshared electron pair not involved in aromaticity.

Specific examples of the nitrogen atom-containing compound include exemplified compounds Nos. 1 to 134 described in paragraphs (0097) to (0221) of JP 2015-046364 A.

### Eighth Embodiment: Formation of Optical Adjustment Layer

In the present invention, a configuration in which an optical adjustment layer is disposed on a negative electrode is preferable.

FIG. 10 exemplifies a configuration of an organic EL element applicable to the present invention, and is a schematic cross-sectional view illustrating a configuration in which an optical adjustment layer (16) is formed on a thin film silver layer (15) having the configuration described above in FIG. 9 (sixth embodiment).

The optical adjustment layer applicable to the present invention plays a role of improving transmittance of a light-transmissive material by an optical interference action.

As a material constituting the optical adjustment layer applicable to the present invention, an existing compound can be used without particular limitation as long as an appropriate refractive index can be obtained. A compound to which a vacuum vapor deposition method can be applied is preferable from a viewpoint of being able to form a film on a negative electrode of an organic EL without damage.

Examples of a material for forming the optical adjustment layer include Al₂O₃ (refractive index 1.6), CeO₃ (refractive index 2.2), Ga₂O₃ (refractive index 1.5), HfO₂ (refractive index 2.0), ITO (indium.tin oxide refractive index 2.1), IZO (indium zinc oxide, refractive index 2.1), MgO (refractive index 1.7), Nb₂O₅ (refractive index 2.3), SiO₂ (refractive index 1.5), Ta₂O₅ (refractive index 2.2), TiO₂ (refractive index 2.3 to 2.5), Y₂O₃ (refractive index 1.9), ZnO (refractive index 2.1), ZrO₂ (refractive index 2.1), AlF₃ (1.4), CaF₂ (1.2 to 1.4), CeF₃ (1.6), GdF₃ (1.6), LaF₃ (1.59), LiF (1.3), MgF₂ (1.4), and NaF (1.3).

### Ninth Embodiment: Application of Electrical Connection Unit (FPC)

In the present invention, a connecting portion between an organic EL panel and an external electrode is preferably electrically connected by a conductive adhesive, and the external electrode is more preferably constituted by a light-transmissive flexible printed circuit (FPC).

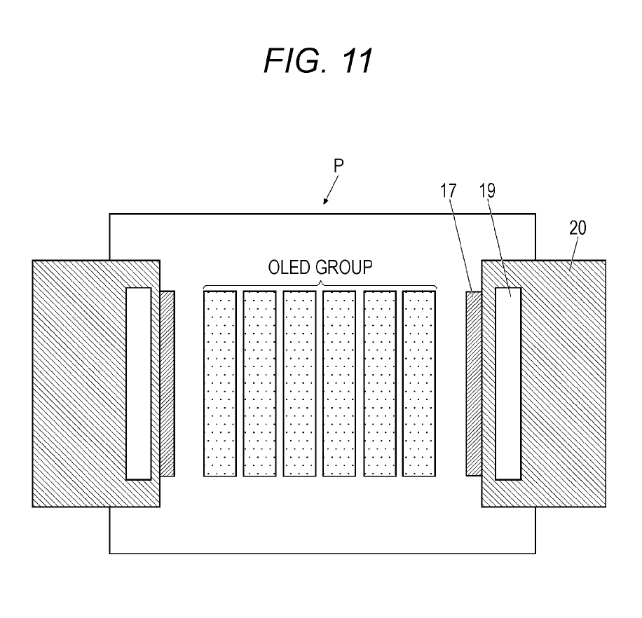

FIG. 11 is a schematic view illustrating an example of an electrical connection method between an organic EL panel applicable to the present invention and an external electrode.

FIG. 11 illustrates an example in which a light-transmissive flexible printed circuit (FPC, 20) as an external electrode is connected via an anisotropic conductive film (ACF, 19) to an extraction electrode (17) disposed at each end portion of an organic EL panel (P) having a plurality of organic EL elements (OLEDs) arranged in parallel.

In formation of the organic EL panel of the present invention, a highly transmissive flexible printed circuit (FPC) can be applied as an electrical connection unit. A flexible printed circuit (FPC) is also called a “flexible printed circuit board” or a “flexible printed wiring board”, and means a substrate obtained by forming an electric circuit on a substrate obtained by sticking a thin and soft base film (polyimide or the like) having an insulating property to a conductive metal such as a copper foil.

An FPC as an electrical connection unit includes a circuit unit on a front surface side of a flexible substrate, and includes wiring on a back surface side thereof

The flexible substrate constituting the electrical connection unit (FPC) is not particularly limited as long as being a transparent and flexible plastic material having sufficient mechanical strength. Examples of the material include a polyimide resin (PI), a polycarbonate resin, a polyethylene terephthalate resin (PET), a polyethylene naphthalate resin (PEN), and a cycloolefin resin (COP). Preferable examples of the material include a polyimide resin (PI), a polyethylene terephthalate resin (PET), and a polyethylene naphthalate resin (PEN).

The circuit unit on a front surface and the wiring on a back surface are preferably formed of a conductive metal material. Examples of the material include gold, silver, copper, and ITO. However, the circuit unit and the wiring are preferably formed of copper in the present invention.

The conductive adhesive for electrically connecting the transparent FPC to the organic EL panel is not particularly limited as long as being a conductive member. However, an anisotropic conductive film (ACF), a conductive paste, or a metal paste is preferable.

Examples of the anisotropic conductive film (ACF) include a layer having fine conductive particles having conductivity, mixed with a thermosetting resin. The conductive particle-containing layer that can be used in the present invention is not particularly limited as long as containing conductive particles as an anisotropic conductive member, and can be appropriately selected according to a purpose. Examples of the conductive particles that can be used as the anisotropic conductive member according to the present invention include metal particles and metal-coated resin particles. Examples of a commercially available ACF include a low temperature curing type ACF applicable also to a resin film, such as MF-331 (manufactured by Hitachi Chemical Co., Ltd.).

Examples of the metal particles include nickel, cobalt, silver, copper, gold, and palladium. These particles may be used singly or in combination of two or more kinds thereof. Among these particles, nickel, silver, and copper are preferable. In order to prevent surface oxidation of these metals, particles with gold or palladium applied onto a surface thereof may be used. Furthermore, particles which have been subjected to insulation coating with a metal protrusion or an organic substance on surfaces thereof may be used.

Examples of the metal-coated resin particles include particles in which a surface of a resin core is coated with any metal of nickel, copper, gold, and palladium. Similarly, particles having gold or palladium applied onto an outermost surface of a resin core may be used. Furthermore, particles which have been subjected to insulation coating with a metal protrusion or an organic substance on a surface of a resin core may be used.

As the metal paste, a silver particle paste, a silver-palladium particle paste, a gold particle paste, a copper particle paste, or the like which is a commercially available metal nanoparticle paste can be appropriately selected to be used. Examples of the metal paste include a silver paste for an organic EL element substrate available from Daiken Chemical Co., Ltd. (CA-6178, CA-6178B, CA-2500E, CA-2503-4, CA-2503N, CA-271, and the like, specific resistance value: 15 to 30 mΩ·cm, formed by a screen printing method, curing temperature: 120 to 200° C.), a paste for LTCC (PA-88 (Ag), TCR-880 (Ag), and PA-Pt (Ag.Pt)), and a silver paste for a glass substrate (US-201 and UA-302, firing temperature: 430 to 480° C.).

### INDUSTRIAL APPLICABILITY

The organic electroluminescence panel of the present invention achieves luminance uniformity, and can be suitably used for various smart devices such as surface light emitters of various lighting apparatuses, a smart phone, and a tablet.

### REFERENCE SIGNS LIST

1 Substrate
2, 10 Gas barrier layer
3 Positive electrode (light-transmissive positive electrode)
4 Carrier transport functional layer group 1
5 Light-emitting layer
6 Carrier transport functional layer group 2
7 Negative electrode (light-transmissive negative electrode)
8 Separator (partition wall)
9 Sealing adhesive layer
11 Sealing substrate
12 Insulating layer
13 Application power supply
14 Base layer
15 Thin film silver layer
16 Optical adjustment layer
17 Extraction electrode
18 Wiring
19 ACF connection area
20 FPC
L Emitted light
OLED Organic EL element
P Organic EL panel
U Organic functional layer unit

1. An organic electroluminescence panel comprising an organic electroluminescence element having a light transmittance of 50% or more at a wavelength of 550 nm during non-emission of light, wherein
in the organic electroluminescence element, a light-emitting area constituted by at least a positive electrode, an organic functional layer unit, and a negative electrode is divided into a plurality of parts on a substrate,
both the positive electrode and the negative electrode constituting the light-emitting area are constituted by light-transmissive electrodes,
the negative electrode is separated by a separator disposed on the positive electrode, and
a positive electrode constituting one of the divided light-emitting areas is electrically connected in series to a negative electrode constituting another adjacent light-emitting area.

2. The organic electroluminescence panel according to claim 1, wherein an insulating layer is disposed between the positive electrode and the separator.

3. The organic electroluminescence panel according to claim 1, wherein the substrate is a light-transmissive glass substrate or flexible resin substrate.

4. The organic electroluminescence panel according to claim 3, wherein the flexible resin substrate has a gas barrier layer.

5. The organic electroluminescence panel according to claim 1, wherein the light-transmissive positive electrode is formed of an oxide semiconductor or a thin film metal or alloy.

6. The organic electroluminescence panel according to claim 1, wherein the light-transmissive negative electrode is formed of at least a thin film metal or alloy.

7. The organic electroluminescence panel according to claim 1, wherein the light-transmissive negative electrode includes a base layer formed using a nitrogen-containing compound and an electrode layer formed of silver or an alloy containing silver as a main component on the base layer.

8. The organic electroluminescence panel according to claim 1, wherein a connecting portion between the organic electroluminescence panel and an external electrode is electrically connected by a conductive adhesive.

9. The organic electroluminescence panel according to claim 1, wherein the plurality of organic electroluminescence elements is sealed with a flexible resin member having a gas barrier layer.

10. The organic electroluminescence panel according to claim 1, wherein the plurality of light-emitting areas is separated from one another by the separators and is arranged in parallel in stripes.

11. The organic electroluminescence panel according to claim 8, wherein the external electrode is formed of a light-transmissive flexible printed circuit.

12. A method for manufacturing an organic electroluminescence panel for manufacturing the organic electroluminescence panel according to claim 1, wherein
the organic electroluminescence panel includes an organic electroluminescence element having a light transmittance of 50% or more at a wavelength of 550 nm during non-emission of light,
in the organic electroluminescence element, a light-emitting area constituted by at least a positive electrode, an organic functional layer unit, and a negative electrode is formed on a substrate while being divided into a plurality of parts,
a pattern in which the negative electrode is separated by a separator disposed on the positive electrode is formed,
a positive electrode constituting one of the divided light-emitting areas is electrically connected in series to a negative electrode constituting another adjacent light-emitting area, and
the positive electrode, the negative electrode, and the separator are formed by a photolithography method.

13. The method for manufacturing an organic electroluminescence panel according to claim 12, wherein an insulating layer is formed between the positive electrode and the separator using a photolithography method.

14. The organic electroluminescence panel according to claim 2, wherein the substrate is a light-transmissive glass substrate or flexible resin substrate.

15. The organic electroluminescence panel according to claim 2, wherein the light-transmissive positive electrode is formed of an oxide semiconductor or a thin film metal or alloy.

16. The organic electroluminescence panel according to claim 2, wherein the light-transmissive negative electrode is formed of at least a thin film metal or alloy.

17. The organic electroluminescence panel according to claim 2, wherein the light-transmissive negative electrode includes a base layer formed using a nitrogen-containing compound and an electrode layer formed of silver or an alloy containing silver as a main component on the base layer.

18. The organic electroluminescence panel according to claim 2, wherein a connecting portion between the organic electroluminescence panel and an external electrode is electrically connected by a conductive adhesive.

19. The organic electroluminescence panel according to claim 2, wherein the plurality of organic electroluminescence elements is sealed with a flexible resin member having a gas barrier layer.

20. The organic electroluminescence panel according to claim 2, wherein the plurality of light-emitting areas is separated from one another by the separators and is arranged in parallel in stripes.
